(19) United States
(12) Patent Application Publication
(10) Pub. No.: US 2025/0246582 A1
(43) Pub. Date: Jul. 31, 2025

(54) STACKED INTEGRATED CIRCUIT DEVICES INCLUDING LOGIC DIE AND MEMORY STACKS

(71) Applicant: QUALCOMM Incorporated, San Diego, CA (US)

(72) Inventors: Yangyang SUN, San Diego, CA (US); Yue LI, San Diego, CA (US); Ryan LANE, San Diego, CA (US)

(21) Appl. No.: 18/428,106

(22) Filed: Jan. 31, 2024

(51) Int. Cl. H01L 25/065; H01L 23/528; H10B 80/00

(52) U.S. Cl. CPC H01L 25/0657; H01L 23/5283; H10B 80/00; H01L 2225/06544

(57) ABSTRACT

A stacked IC device includes a first memory stack including two or more memory dies coupled to a substrate and a second memory stack including two or more memory dies coupled to the substrate. The stacked IC device also includes a logic die electrically connected to memory dies of the first memory stack through face-to-face connections to a top die of the first memory stack and electrically connected to memory dies of the second memory stack through face-to-face connections to a top die of the second memory stack. The stacked IC device further includes a patch component disposed in a region between the first memory stack and the second memory stack. The patch component includes conductors that electrically connect the logic die to the substrate.

### FIELD

Various features relate to stacked integrated circuit devices including logic die and memory stacks.

### BACKGROUND

Electrical connections exist at each level of a system hierarchy of an integrated circuit (IC) device. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. Recently, the number of interconnect levels for circuitry has substantially increased due to the large number of devices that are now interconnected in a modern electronic device. The increased number of interconnect levels for supporting the increased number of devices involves more intricate manufacturing processes.

During the design of modern integrated circuit devices, there is often a conflict between various design goals. For example, in some applications, it is desirable to limit IC package size and it is desirable to improve heat dissipation. However, generally, smaller IC packages have less area for removal of heat. Thus, reducing IC package size can tend to reduce heat dissipation. Similar conflicts can arise between heat dissipation and processing performance because higher performance processors tend to generate more heat. Further, the goal of reducing cost can conflict with almost any other improvement goal. Thus, it is challenging to provide high performance IC devices that can meet the various design goals. These challenges are especially significant for mobile applications where power constraints, device size, processing performance, heat dissipation, cost, and many other factors come into play simultaneously.

### SUMMARY

Various features relate to IC devices.

One example provides a stacked IC device that includes a first memory stack including two or more memory dies coupled to a substrate and a second memory stack including two or more memory dies coupled to the substrate. The stacked IC device also includes a logic die electrically connected to memory dies of the first memory stack through face-to-face connections to a top die of the first memory stack and electrically connected to memory dies of the second memory stack through face-to-face connections to a top die of the second memory stack. The stacked IC device further includes a patch component disposed in a region between the first memory stack and the second memory stack. The patch component includes conductors that electrically connect the logic die to the substrate.

Another example provides a stacked IC device that includes a first memory stack including two or more memory dies coupled to a substrate and a second memory stack including two or more memory dies coupled to the substrate. The stacked IC device further includes a first logic die electrically connected to memory dies of the first memory stack through face-to-face connections to a top die of the first memory stack and a second logic die electrically connected to memory dies of the second memory stack through face-to-face connections to a top die of the second memory stack. The stacked IC device further includes a patch component disposed in a region between the first memory stack and the second memory stack. The patch component includes first conductors that electrically connect the first logic die to the substrate and second conductors that electrically connect the second logic die to the substrate.

Another example provides a method for fabricating a stacked IC device that includes coupling a plurality of memory stacks to a substrate, where each memory stack includes two or more memory dies. The method also includes electrically connecting a patch component to the substrate in a region between two or more memory stacks of the plurality of memory stacks. The method further includes electrically connecting a logic die to the substrate through the patch component, and, face-to-face, to top dies of the two or more memory stacks.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1A illustrates a schematic top view of an example of an exemplary stacked IC device.

FIG. 1B illustrates a schematic elevational view of an example of the exemplary stacked IC device of FIG. 1A.

FIG. 1C illustrates a schematic perspective view of an example of the exemplary stacked IC device of FIG. 1A.

FIG. 2 illustrates a schematic cross-sectional view of another example of the exemplary stacked IC device of FIG. 1A.

FIG. 3 illustrates a schematic cross-sectional view of another example of the exemplary stacked IC device of FIG. 1A.

FIG. 4 illustrates a schematic cross-sectional view of another example of the exemplary stacked IC device of FIG. 1A.

FIG. 5 illustrates a schematic cross-sectional view of another example of the exemplary stacked IC device of FIG. 1A.

FIG. 6 illustrates a schematic cross-sectional view of another example of the exemplary stacked IC device of FIG. 1A.

FIG. 7 illustrates a schematic cross-sectional view of another example of the exemplary stacked IC device of FIG. 1A.

FIG. 8 illustrates a schematic cross-sectional view of another example of the exemplary stacked IC device of FIG. 1A.

FIG. 9 illustrates a schematic cross-sectional view of another example of the exemplary stacked IC device of FIG. 1A.

FIGS. 10A and 10B, together, illustrate an exemplary sequence for fabricating an example of a patch component.

FIGS. 11A and 11B, together, illustrate an exemplary sequence for fabricating another example of a patch component.

FIGS. 12A and 12B, together, illustrate an exemplary sequence for fabricating another example of a patch component.

FIGS. 13A and 13B, together, illustrate an exemplary sequence for fabricating another example of a patch component.

FIGS. 14A and 14B, together, illustrate an exemplary sequence for fabricating an example of a stacked IC device.

FIGS. 15A and 15B, together, illustrate an exemplary sequence for fabricating an example of a stacked IC device.

FIG. 16 illustrates an exemplary sequence for fabricating another example of a stacked IC device.

FIG. 17 illustrates various electronic devices that may integrate a die, a stacked IC device, an electronic circuit, an integrated device, a package, and/or a device package described herein.

### DETAILED DESCRIPTION

Particular aspects of the disclosure describe stacked integrated circuit (IC) devices that include one or more logic dies and multiple memory stacks. The logic die(s) can include a single logic die or several logic dies configured to work independently or in conjunction with one another. For example, the logic die(s) can include chiplets configured to interact with one another to perform various operations. In the disclosed examples, the logic die(s) are electrically connected, face-to-face, with a top die of each of two or more memory stacks and are electrically connected to a substrate by conductors that extend through a region between two of the memory stacks.

The face-to-face electrical connections between the logic die(s) and the top dies of the memory stacks provides short interconnect paths which improves the data rate of memory access as compared to configurations in which logic and memory dies are interconnected by less direct routes, such as side-by-side configurations and package-on-package configurations. One problem associated with coupling logic and memory dies face-to-face is how to route other connections of the logic dies (e.g., power connections and other input/output (I/O) connections). Examples disclosed herein solve this problem by routing many (or all) of these other connections of the logic die(s) through a patch component disposed in a region between at least two of the memory stacks. The patch component includes a body and conductors that extend through the body to electrically connect the logic die(s) to the substrate.

In the context of this disclosure, a “face” of a die refers to a surface of the die adjacent to an active region of the die. For example, the active region can include various layers and structures that define circuit elements, such as transistors, conductors, passive circuit elements (e.g., resistors, inductors, capacitors, etc.), and a power delivery network. In this example, the face of the die corresponds to the side of the die that bounds the active region. In contrast, a “back” of the die refers to an opposite side of the die which bounds an inactive region of the die. For example, the inactive region typically includes undoped monocrystalline semiconductive material, other inactive layers (e.g., passivation layers), or both.

As used herein, the term “stacked” (as in “stacked dies” and/or “stacked ICs”) refer to arrangements in which one die or device (e.g., a first die) is disposed over, including directly over or partially over, another die or device (e.g., a second die). A “memory stack” refers to two or more memory dies (and possibly other dies, such as memory controllers) arranged in a stacked configuration. As used herein, “face-to-face” refers to a stacked die arrangement in which a first die and a second die are stacked such that a normal of the face of the first die is antiparallel to a normal of the face of the second die. Put another way, the face of the first die is toward the face of the second die, and the backs of the first and second dies are oriented away from one another.

Electrically connecting a face of a top die of a memory stack to a face of a logic die in a face-to-face configuration enables the use of short, high-density (e.g., small pitch) interconnections between the memory stack and the logic die. Shorter interconnections are generally subject to less resistive loss, resulting in improved power efficiency and less heat generation. Additionally, shorter interconnections enable faster signal exchange than longer interconnections.

In some implementations, the patch component includes other features in addition to the conductors. For example, the patch component can include traces to form conductive paths between the logic die(s) and other components (e.g., one or more other logic dies). As another example, the patch component can include passive circuit elements, such as capacitors, inductors, and/or resistors. The patch component can include a single body through which the conductors extend, or the patch component can include multiple stacked and interconnected bodies which together define the conductors.

As compared to conventional approaches, such as side-by-side or package-on-package configurations, the face-to-face arrangement of logic die(s) and memory stacks disclosed herein enables low-cost fabrication of IC devices that have a small form factor, high-density logic-memory interconnection, high-speed logic-memory communication, improved thermal management, improved power distribution network performance, as well as other benefits. For example, since the thickness of the logic die(s) used in the disclosed embodiments does not result in longer conductive paths, the logic die(s) can have thick inactive regions to facilitate heat transfer, resulting in improved thermal management. As another example, the face-to-face electrical connections can reduce reliance on horizontal connections and/or redistribution layers, which reduces manufacturing cost and can reduce losses due to shortened end-to-end conductive path length.

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure aspects of the disclosure.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

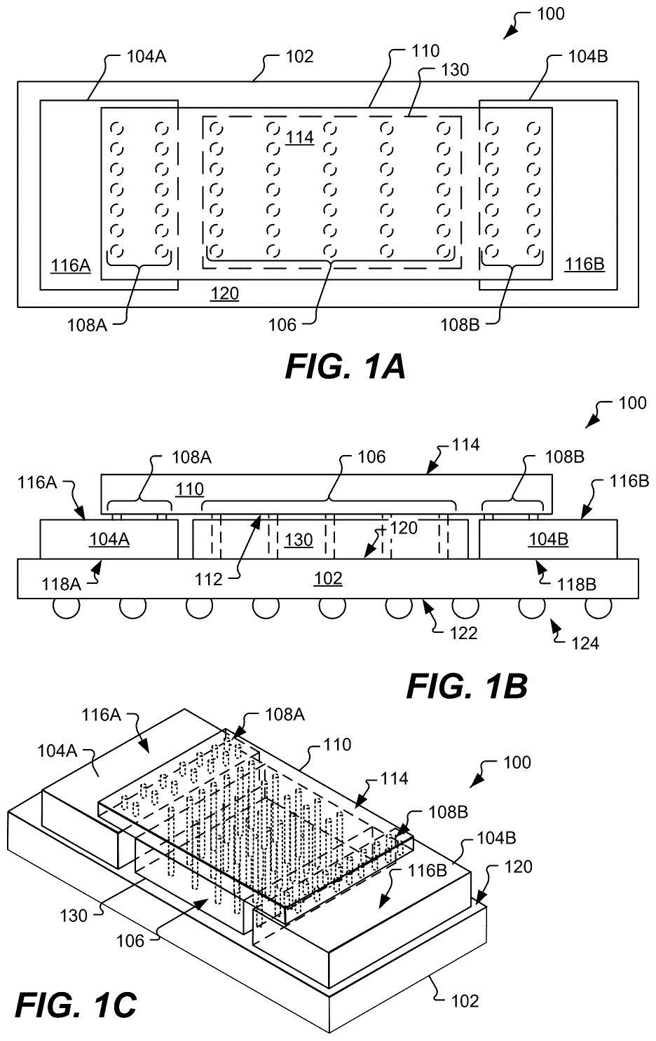

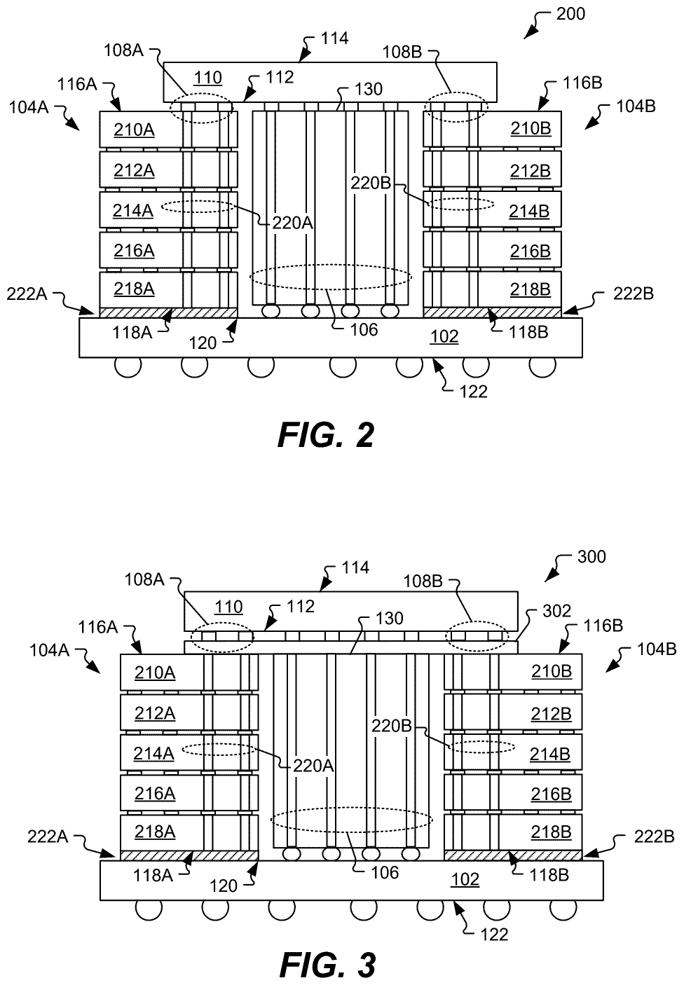

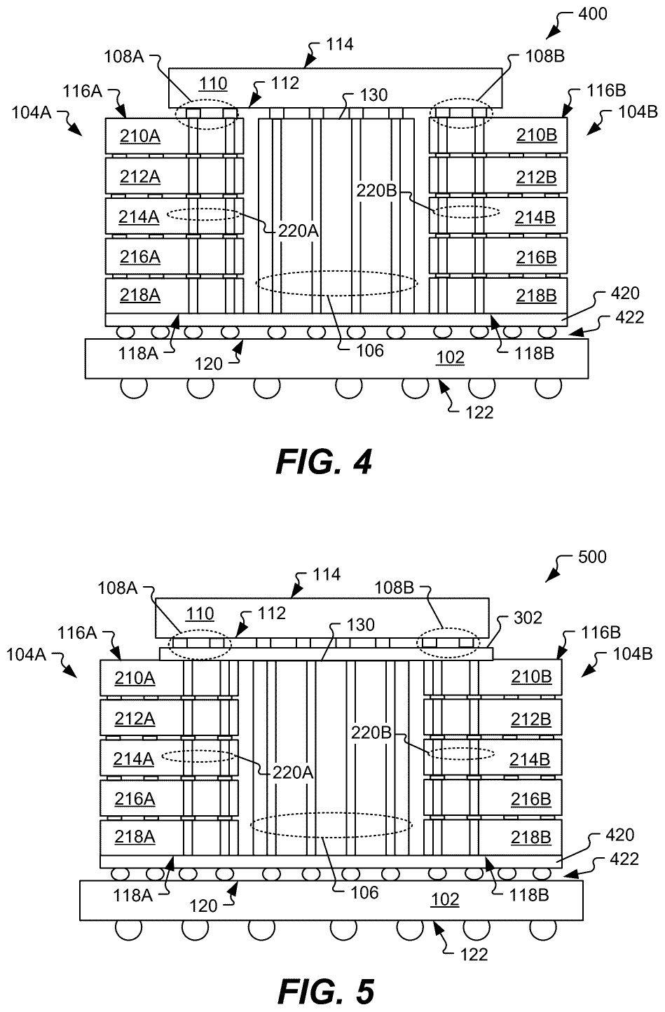

In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1A, multiple memory stacks are illustrated and associated with reference numbers 104A and 104B. When referring to a particular one of these memory stacks, such as memory stack 104A, the distinguishing letter “A” is used. However, when referring to any arbitrary one of these memory stacks or to these memory stacks as a group, the reference number 104 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices has led to increasing complexity of ICs. Often, more complex ICs have more complex interconnection schemes to enable interaction between ICs of a device. The number of interconnect levels for circuitry has substantially increased due to the large number of devices that are now interconnected in state-of-the-art applications, such as in ICs for mobile devices.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

State-of-the-art applications often demand IC devices that have a small form factor, low cost, a tight power budget, and high electrical performance. IC package design has evolved to meet these divergent goals for particular applications, such as mobile devices that support multimedia. For example, fan-out (FO) wafer level packaging (WLP) or FO-WLP process technology is a development in packaging technology that is useful for mobile applications. This chip first FO-WLP process technology solution provides flexibility to fan-in and fan-out connections from a die to package balls. In addition, this solution also provides a height reduction of a first level interconnect between the die and the package balls of IC package. These IC packages, however, are susceptible to power and signal routing issues when multiple dies are arranged within the small form factor.

Stacked die schemes and chiplet architectures are becoming more common as significant power performance area (PPA) yield enhancements are demonstrated for stacked die and chiplet architecture product lines. Forming an IC device using stacked dies, chiplets, or both, can provide various benefits as compared to providing the same functional circuitry in one monolithic chip. For example, each chiplet is smaller than a single monolithic die that includes all of the same functional circuit blocks. Since yield loss, and costs due to yield loss, in IC manufacturing tends to increase as the die size increases, using smaller dies can reduce yield loss (i.e., increase yield) of the IC manufacturing process. Another benefit is that the chiplets can be fabricated in different locations and/or by different manufacturers, and in some cases, using different fabrication technologies (e.g., different fabrication technology nodes). As an example, one die of a chiplet-based integrated device can include components (e.g., interconnects, transistors, etc.) that have a first minimum size, and another die of the chiplet-based integrated device can include components (e.g., interconnects, transistors, etc.) that have a second minimum size, where the second minimum size is greater than the first minimum size.

In contrast, all of the circuitry of a monolithic die is fabricated using the same fabrication technologies and equipment. As a result, when manufacturing a monolithic die, the entire die may be subject to the tightest manufacturing constraint of the most complex component of the monolithic die. However, when using chiplets, different chiplets can be manufactured using different fabrication technologies (e.g., different fabrication technology nodes), and only the chiplet or chiplets that include the most complex components are subjected to the tightest manufacturing constraints. In this arrangement, chiplets fabricated using less expensive and/or higher yield fabrication technologies can be integrated with chiplets fabricated using more expensive and/or lower yield fabrication technologies to form an IC (e.g., the stacked IC device), resulting in overall savings. Still further, in some cases, as technology improves, the design of a chiplet can be changed. New chiplet designs may be used in conjunction with older chiplet designs to form IC devices, which improves manufacturing flexibility and reduces design costs.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture. As used herein, the term “die” can include a chiplet or a monolithic IC. For example, a logic die can be configured to operate independently of other logic dies (e.g., as a monolithic IC). Alternatively, the logic die can include a first set of functional logic blocks that are configured to operate in conjunction with functional logic blocks of one or more other logic dies (e.g., in a chiplet architecture).

A three-dimensional (3D) integrated circuit (3D IC) includes a set of stacked and interconnected dies. Generally, a 3D IC architecture can achieve higher performance, increased functionality, lower power consumption, and/or smaller footprint, as compared to providing the same circuitry in a monolithic die or in a two-dimensional (2D) IC structure.

### Exemplary Stacked IC Device

FIGS. 1A, 1B, and IC illustrate schematic top, elevational, and perspective views, respectively, of an example of an exemplary stacked IC device 100. The stacked IC device 100 includes a memory stack 104A, a memory stack 104B, a logic die 110, a patch component 130, and a substrate 102. As described in more detail below, the logic die 110 is electrically connected, face-to-face, to a top die of each of the memory stacks 104 and is electrically connected to the substrate 102 by conductors 106 (illustrated in dashed lines to indicate that the conductors 106 are not visible in the elevational view illustrated) that extend through the patch component 130.

The logic die 110 includes active circuitry (e.g., a plurality of interconnected transistors) arranged to form various functional blocks. Examples of functional blocks that can be included in the logic die 110 include, without limitation, arithmetic blocks, logic blocks, flow control blocks, and combinations thereof. In some embodiments, the logic die 110 also includes transistors interconnected to form local memory units, such as registers or caches to temporarily store data during operations.

The active circuitry of the logic die 110 is formed in an active region that is bounded by a face 112, which is shown in FIG. 1B, of the logic die 110. The face 112 of the logic die 110 is opposite a back 114 of the logic die 110. For example, in FIG. 1B, the logic die 110 is illustrated in a face-down orientation in which the face 112 is toward the substrate 102, and the back 114 is oriented away from the substrate 102.

Each memory stack 104 includes a plurality of memory dies. In some embodiments, each of the memory stacks 104 also includes a memory controller associated with memory dies of the memory stack 104. The memory dies include active circuitry (e.g., a plurality of interconnected transistors) arranged to form blocks of memory cells. For example, the memory dies can include dynamic-random access memory (DRAM) dies (e.g., double-data rate (DDR) memory dies), high bandwidth memory (HBM) dies, etc. In this context, “high bandwidth memory” includes arrangements of dies that conform to a High Bandwidth Memory (HBM) DRAM standard as published by the JEDEC Solid State Technology Association, and similar arrangements. The memory dies may also include other circuits, such as read/write circuitry, address decoders, etc.

The top die of each memory stack 104 includes active circuitry formed in an active region that is bounded by a face 116 of the top die. In some examples, a bottom of each memory stack 104 is bounded by a back 118 of a bottom die of the memory stack 104. In such examples, each die of the memory stack 104 is oriented, in a face-up orientation. In this context, “face-up” refers to a face of a die being oriented away from the substrate 102, and a back of the die being oriented toward the substrate 102. In some examples, dies of the memory stack 104 include through silicon vias (TSVs) to provide electrical connections between the top die of the memory stack 104, the bottom die of the memory stack 104, and dies between the top die and the bottom die of the memory stack 104.

The logic die 110 is stacked on the memory stacks 104 and electrically connected, face-to-face, to the top die of each memory stack 104. For example, in FIGS. 1A-1C, interconnects 108A electrically connect the logic die 110 to the top die of memory stack 104A, and interconnects 108B electrically connect the logic die 110 to the top die of the memory stack 104B. The interconnects 108 can include conductive pillars (e.g., copper (Cu) pillars), solder bumps, pillar bumps (e.g., pillars that include an attached solder cap), or other types of die-to-die electrical interconnects.

The substrate 102 includes a plurality of metal layers separated by dielectric layers. In this example, the metal layers are patterned to define metal lines, and selectively interconnected by conductive vias to define conductive paths between on-package contacts on a top 120 of the substrate 102 and off-package contacts 124 on a bottom 122 of the substrate 102. In particular examples, the substrate 102 includes redistribution layers built up on other components of the stacked IC device 100. In other examples, the substrate 102 includes a pre-formed arrangement of layers that are attached to other components of the stacked IC device 100.

The patch component 130 includes a body in which the conductors 106 are embedded. The body of the patch component 130 can include a semiconductor (e.g., silicon) material or a polymer or polymer-based material (such as a mold compound, one or more prepreg layers, or another composite material that includes a filler within a polymer matrix). In such embodiments, the patch component 130 can be coupled to the substrate 102 such that an upper surface of the patch component 130 is substantially coplanar with faces 116 of top dies of the memory stacks 104. In some embodiments, the patch component 130 can include other circuitry in addition to the conductors 106, such as active circuitry (e.g., transistors), passive circuitry (e.g., conductive traces, capacitors, inductors, resistors, etc.).

A height of the conductors 106 is related to a distance between the face 112 of the logic die 110 and the top 120 of the substrate 102. Since the logic die 110 is coupled face-to-face with the top die of each of the memory stacks 104, the distance between the face 112 of the logic die 110 and the top 120 of the substrate 102 is related to the height of the memory stacks 104. In some embodiments, the patch component 130 can include a layered arrangement to provide sufficient height to the patch component 130 to interconnect the logic die 110 and the substrate 102.

In some embodiments, the stacked IC device 100 includes one or more redistribution layers (RDLs). For example, RDL(s) can be coupled to the logic die 110, in which case the interconnects 108, the conductors 106, or both, are electrically connected to the circuitry of the logic die 110 through the RDL(s).

Although the stacked IC device 100 is illustrated in FIGS. 1A-1C as including a single logic die 110 and two memory stacks 104, the stacked IC device 100 can include more than one logic die 110, more than two memory stacks 104, or both. In an embodiment in which the stacked IC device 100 includes two or more logic dies 110, the logic dies 110 may be electrically connected to one another via conductive paths through the substrate 102, via conductive paths through the patch component 130, via an interposer or RDLs between the logic dies 110 and the patch component 130, or a combination thereof. In some embodiments in which the stacked IC device 100 includes more than two memory stacks 104, a single logic die 110 can be electrically connected to all of the memory stacks 104.

In some embodiments, the stacked IC device 100 can include devices, dies, or components, in addition to those illustrated in FIGS. 1A-1C. For example, the stacked IC device 100 can correspond to or be included within an integrated device that includes communications circuitry (e.g., one or more wireless transceivers, one or more modems, etc.), sensors (e.g., global positioning system sensors, inertial sensors, image sensors, etc.), special-purpose or general-purpose processors (e.g., central processing units (CPUs), graphics processing units (GPUs), artificial intelligence processing units, various co-processors and accelerator, etc.).

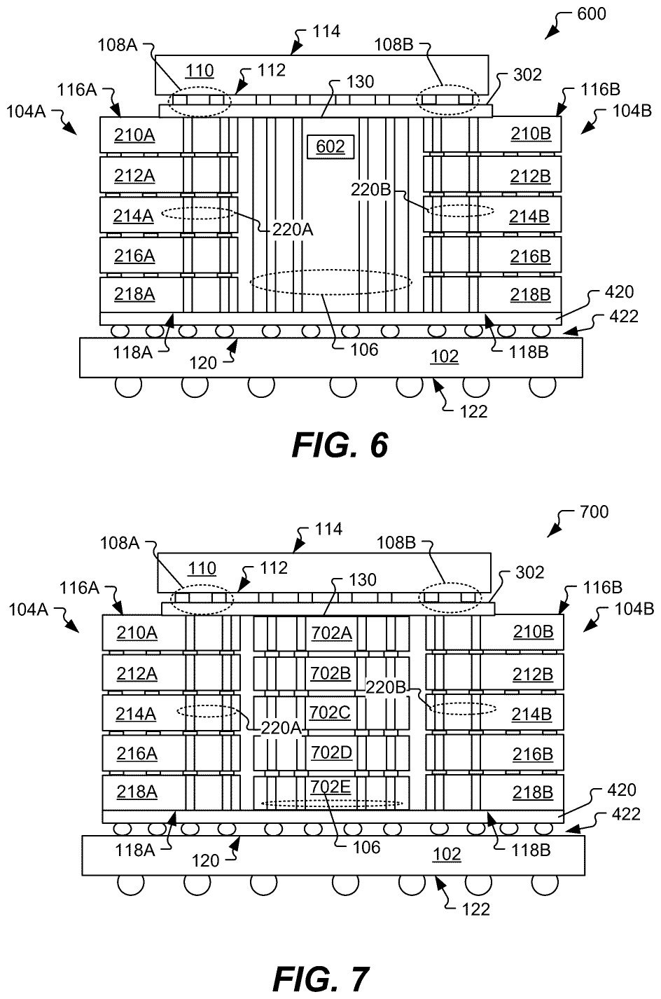

FIGS. 2-7 illustrate schematic cross-sectional views of examples of exemplary stacked IC devices. The stacked IC devices of FIGS. 2-7 are examples of the stacked IC device 100 of FIGS. 1A-1C that each include a single logic die 110. For example, the stacked IC devices of FIGS. 2-7 each include the memory stack 104A, the memory stack 104B, the logic die 110, the patch component 130, and the substrate 102 described with reference to FIGS. 1A-1C. Except as otherwise specifically indicated, each of the stacked IC devices of FIGS. 2-7 can include any of the features, functions, and/or alternative configurations described with reference to FIGS. 1A-1C.

In FIGS. 2-7, each of the memory stacks 104 is illustrated as including five dies. For example, the memory stack 104A includes a top die 210A, a memory die 212A, a memory die 214A, a memory die 216A, and a bottom die 218A. Further, the memory stack 104B includes a top die 210B, a memory die 212B, a memory die 214B, a memory die 216B, and a bottom die 218B. In a particular aspect, at least one die of each memory stack 104 includes memory control circuitry (e.g., is a memory controller) and remaining dies of the memory stack 104 include memory circuitry (e.g. are memory dies). For example, in FIGS. 2-7, the top die 210 of each memory stack 104 corresponds to or includes a memory controller, and the remaining dies of the memory stack 104 (e.g., a memory die 212, a memory die 214, a memory die 216, and a bottom die 218) are memory dies. In other examples, the memory control circuitry is integrated within the logic die 110, and each die (including the top die 210) of each memory stack 104 is a memory die. Dies of each of the memory stacks 104 are interconnected by conductors 220 (e.g., TSVs) that extend through each die. For example, the dies of the memory stack 104A are interconnected by conductors 220A, and the dies of the memory stack 104B are interconnected by the conductors 220B.

In a stacked IC device 200 of FIG. 2, the face 112 of the logic die 110 is electrically connected, by interconnects 108, directly to the face 116 of the top die 210 of each memory stack 104. To illustrate, in this example, no RDLs or interposers are between the face 112 of the logic die 110 and the face 116 of the top die 210 of each memory stack 104. Direct connection of the logic die 110 and the memory stacks 104 may enable shorter signal paths between the logic die 110 and the memory stacks 104 than configurations that include less direct connections, such as connections through RDLs or interposers.

Further, in FIG. 2, a back 118 of the bottom die 218 of each of the memory stacks 104 is coupled to a top 120 of the substrate 102 by an adhesive layer 222. For example, the back 118A of the bottom die 218A is coupled to the top 120 of the substrate 102 by adhesive layer 222A, the back 118B of the bottom die 218B is coupled to the top 120 of the substrate 102 by adhesive layer 222B.

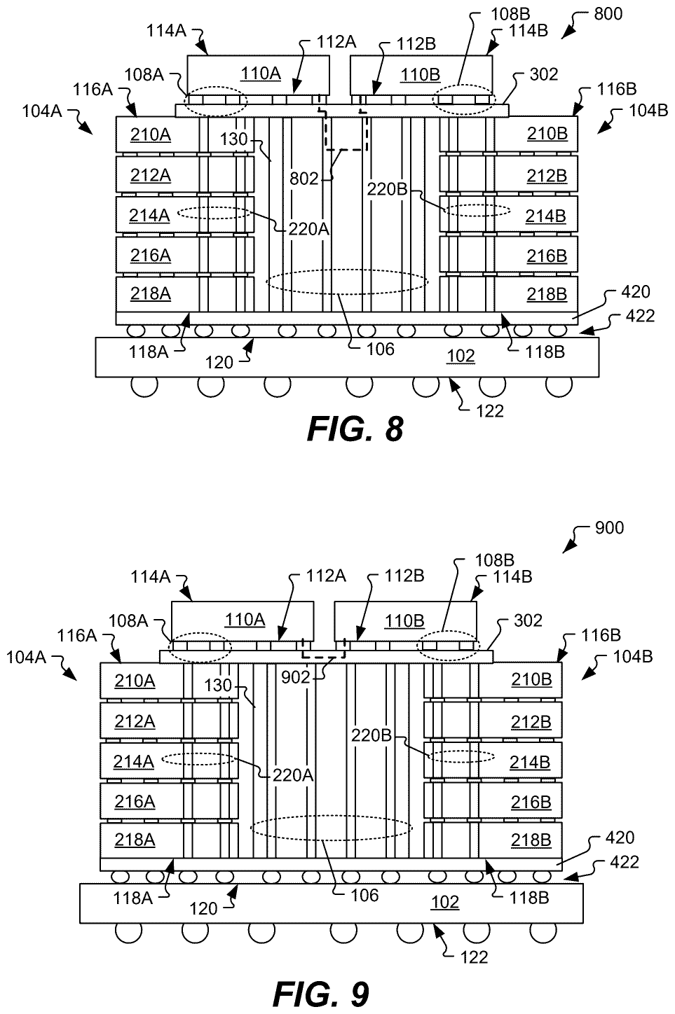

In a stacked IC device 300 of FIG. 3, the back 118 of the bottom die 218 of each of the memory stacks 104 is coupled to a top 120 of the substrate 102 by an adhesive layer 222 similar to the arrangement illustrated in FIG. 2. However, in FIG. 3, the face 112 of the logic die 110 is electrically connected, through interconnects 108 and RDLs 302, to the face 116 of the top die 210 of each memory stack 104. In this example, the RDLs 302 provide longer signal paths between the logic die 110 and the memory stacks 104 than in the example illustrated in FIG. 2; however, the RDLs 302 facilitate remapping of contacts of the logic die 110 and/or the memory stacks 104, which may facilitate use of the memory stacks 104 with various logic dies 110 (e.g., for different product lines) and can accommodate other design or circuit layout constraints. For example, in some cases, it may be challenging to position all of the memory input/output (I/O) contacts of the logic die 110 in a region directly above the memory stacks 104. In this example, the RDLs 302 can be used to remap the memory I/O contacts of the logic die 110 to facilitate connection to the memory stacks 104.

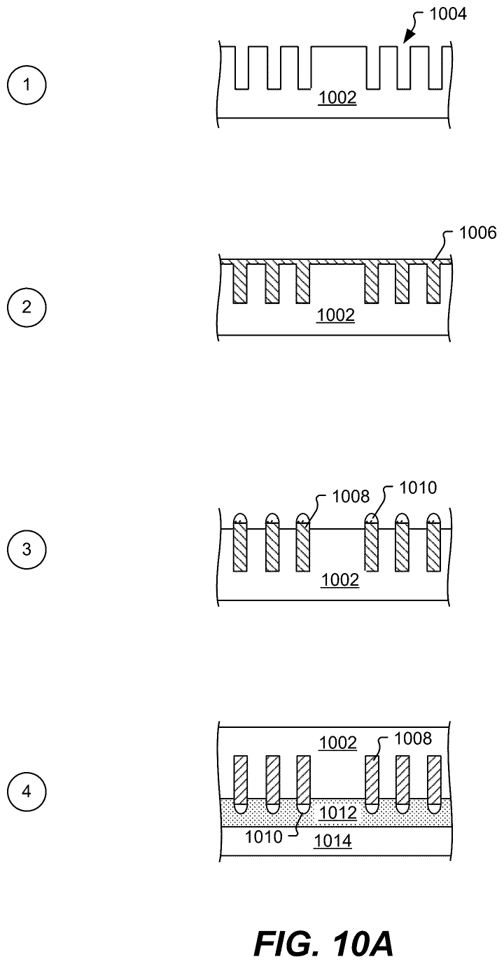

In a stacked IC device 400 of FIG. 4, the face 112 of the logic die 110 is electrically connected, by interconnects 108, directly to the face 116 of the top die 210 of each memory stack 104 similar to the arrangement illustrated in FIG. 2 (e.g., RDLs are between the face 112 of the logic die 110 and the face 116 of the top die 210 of each memory stack 104). However, in FIG. 4, RDLs 420 are disposed between the bottom dies 218 of each of the memory stacks 104 and the substrate 102 and between the bottom of the patch component 130 and the substrate 102. The RDLs 420 are electrically connected to the substrate 102 through interconnects 422. The RDLs 420 facilitate remapping of contacts on the top 120 of the substrate 102 and contacts of the patch component 130. In some embodiments, the RDLs 420 can function as a package substrate of the stacked IC device 400.

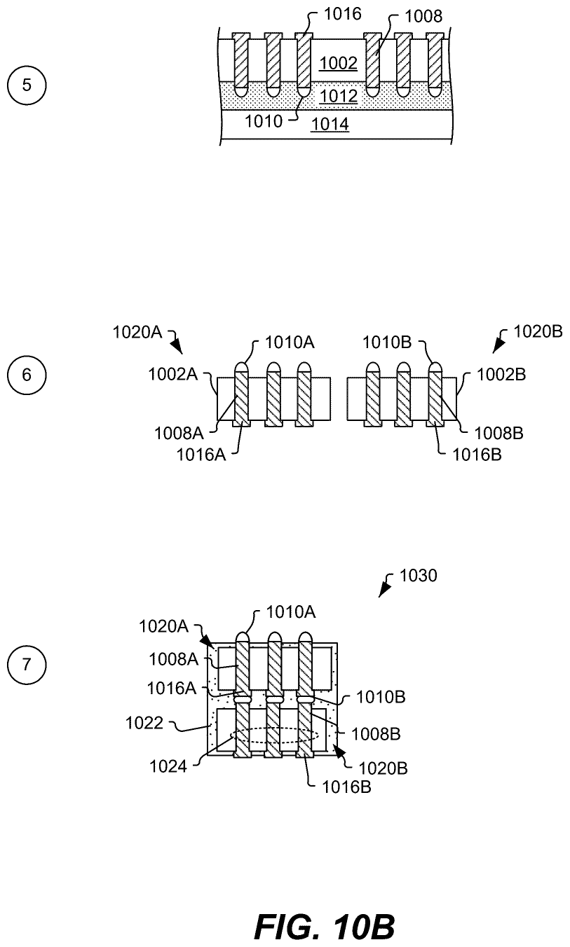

In a stacked IC device 500 of FIG. 5, the face 112 of the logic die 110 is electrically connected, through interconnects 108 and RDLs 302, to the face 116 of the top die 210 of each memory stack 104, and the RDLs 420 are disposed between the bottom dies 218 of each of the memory stacks 104 and the substrate 102 and between the bottom of the patch component 130 and the substrate 102. The RDLs 420 facilitate remapping of contacts on the top 120 of the substrate 102 and contacts of the patch component 130, and the RDLs 302 facilitate remapping of contacts of the logic die 110 and/or the memory stacks 104.

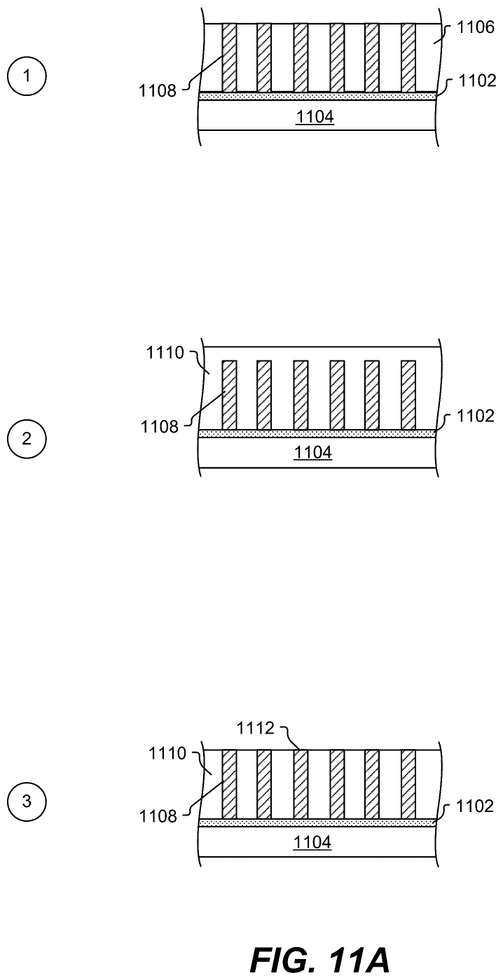

In FIG. 6, the patch component 130 includes circuitry 602. The circuitry 602 can include, for example, active components (e.g., transistors) and/or passive components (e.g., inductors, conductors, resistors, etc.). As one example, the circuitry 602 can include capacitors that are electrically connected to a power distribution network of the logic die 110 to improve performance of the power distribution network.

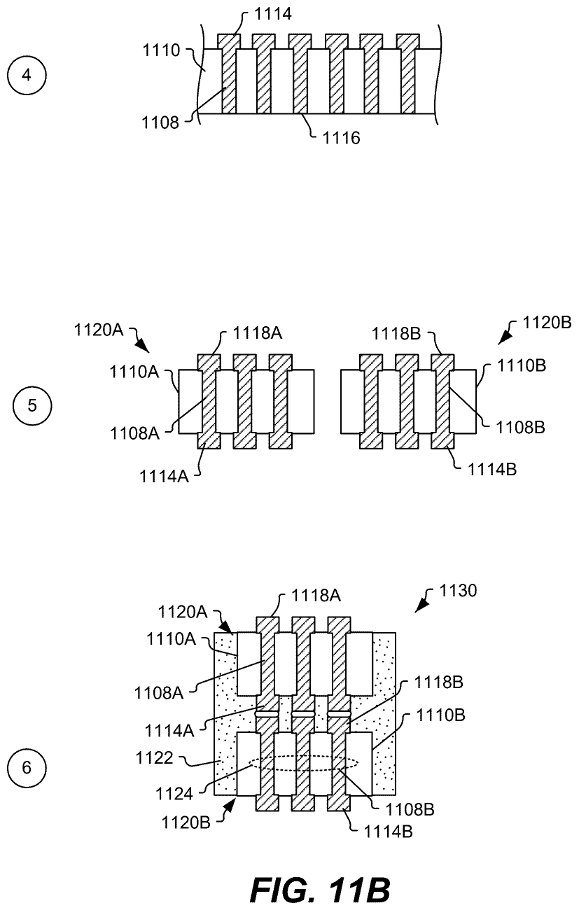

In FIG. 7, the patch component 130 is formed of a plurality of stacked and electrically interconnected layers 702 that together define the conductors 106. In the example illustrated in FIG. 7, the patch component 130 is illustrated with five layers, including a layer 702A, a layer 702B, a layer 702C, a layer 702D, and a layer 702E. In other examples, the patch component 130 includes more than five layers 702 or fewer than five layers 702. For example, a count of layers 702 of the patch component 130 may vary depending on the count of dies of the memory stacks 104. To illustrate, the count of layers 702 of the patch component 130 may be equal to the count of dies of the memory stacks 104. Alternatively, the count of layers 702 of the patch component 130 may be different from the count of dies of the memory stacks 104. For example, the count of dies of the memory stacks 104 can be a multiple of the count of the layers 702 of the patch component 130.

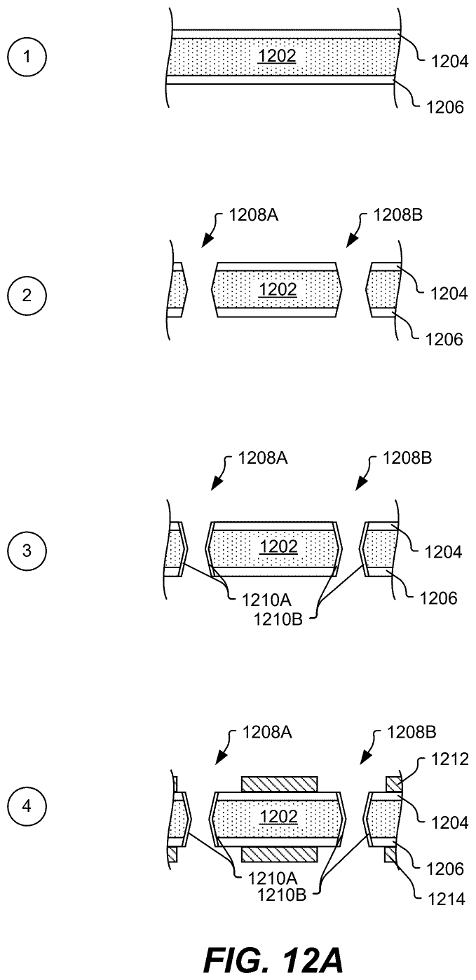

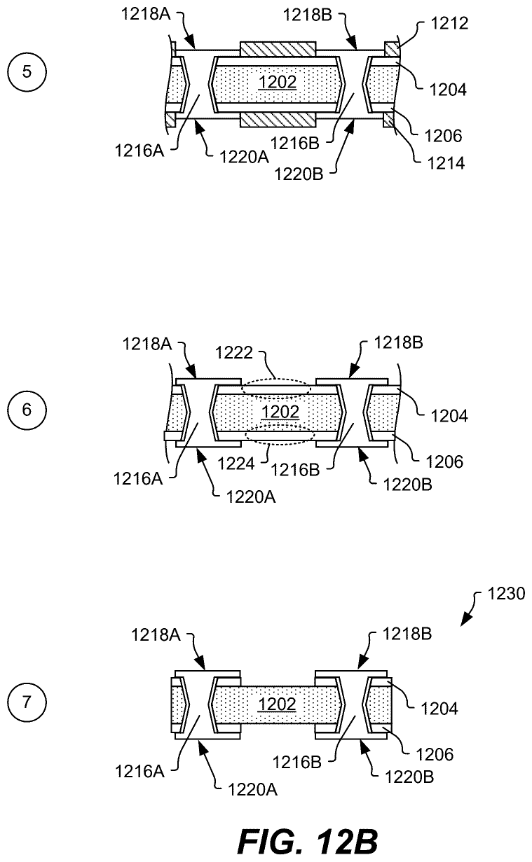

FIGS. 8 and 9 illustrate schematic cross-sectional views of other examples of exemplary stacked IC devices 800 and 900, respectively. In a particular aspect, the stacked IC devices 800 and 900 represent examples of the stacked IC device 100 of FIGS. 1A-1C that include at least two logic dies 110. Except as otherwise specifically indicated, the stacked IC device 800 and 900 can include any of the features, functions, and/or alternative configurations described with reference to FIGS. 1A-IC.

In each of FIGS. 8 and 9, a logic die 110A is electrically connected, face-to-face, with the top die 210A of the memory stack 104A, and a logic die 110B is electrically connected, face-to-face, with the top die 210B of the memory stack 104B. Each of the logic dies 110 is electrically connected to the substrate 102 via the conductors 106 of the patch component 130. In some embodiments, each of the logic dies 110 is also connected, face-to-face, with top dies of one or more additional memory stacks 104.

In each of FIGS. 8 and 9, one or more conductive paths electrically connect the logic die 110A and the logic die 110B to one another. For example, in FIG. 8, a conductive path 802 extends through one of the conductors of the RDLs 302, through one or more of the conductors 106, through another one or more of the conductors 106, and through another one or more of the conductors of the RDLs 302. Thus, in FIG. 8, a portion of the conductive path 802 between the logic dies 110 extends through the conductors 106. In FIG. 9, a conductive path 902 extends through one of the conductors of the RDLs 302. In some embodiments, aspects of FIGS. 8 and 9 may be combined. For example, a stacked IC device can include the conductive path 802 and the conductive path 902.

Although each of FIGS. 2-7 illustrate memory stacks 104 that include five dies, memory stacks 104 of a stacked IC device according to embodiments described herein can include more than five dies or fewer than five dies. For example, a memory stack 104 can include two memory dies, in which case memory control circuitry can be integrated within one or both of the memory dies, or can be separate from the memory dies, such as integrated within a logic die 110 or another component of the stacked IC device. As another example, a memory stack 104 can include two memory dies and a memory controller. As another example, a memory stack 104 can include four, eight, sixteen, thirty-two, or some other number of memory dies.

Further, although each of the stacked IC devices of FIGS. 1-9 illustrate memory stacks 104, logic dies 110, patch components 130, and substrates 102, a stacked IC device according to embodiments described herein can include additional components. For example, a stacked IC device can include one or more dies that include communication circuitry (e.g., wired- or wireless-communication circuitry).

### Exemplary Sequences for Fabricating Patch Components

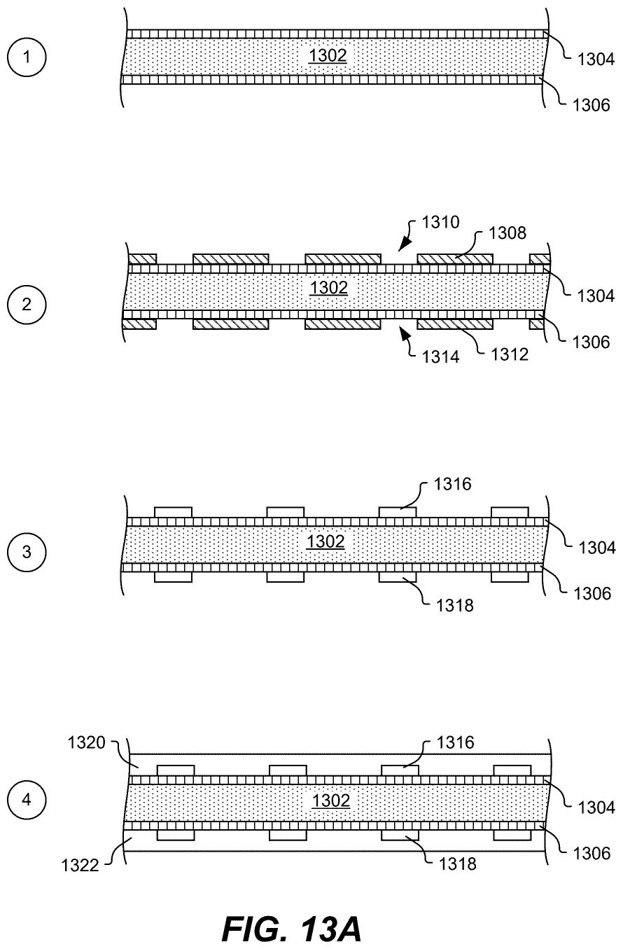

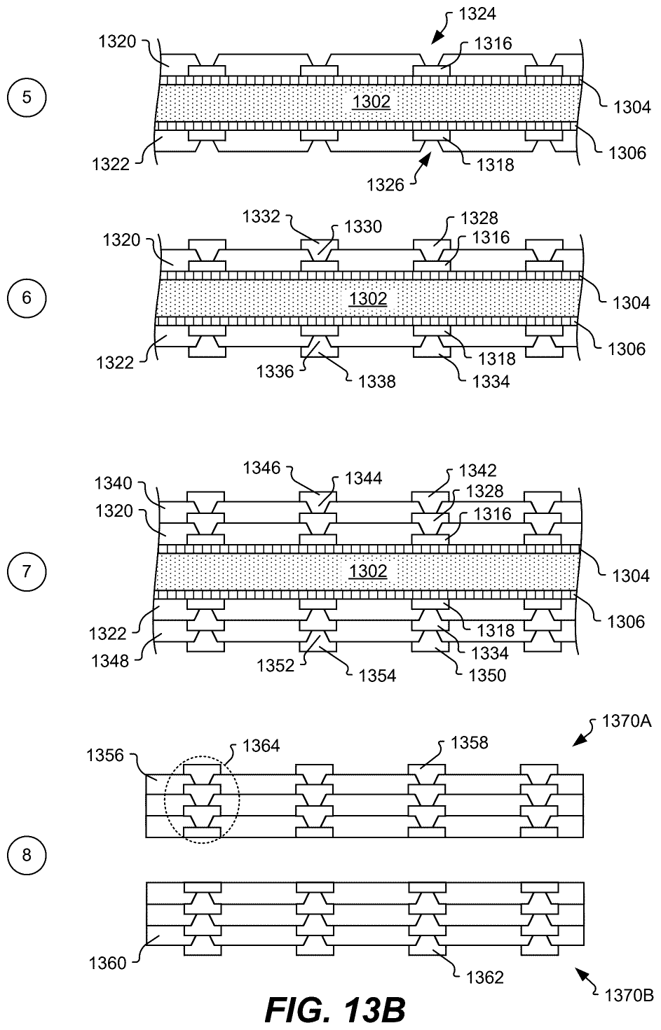

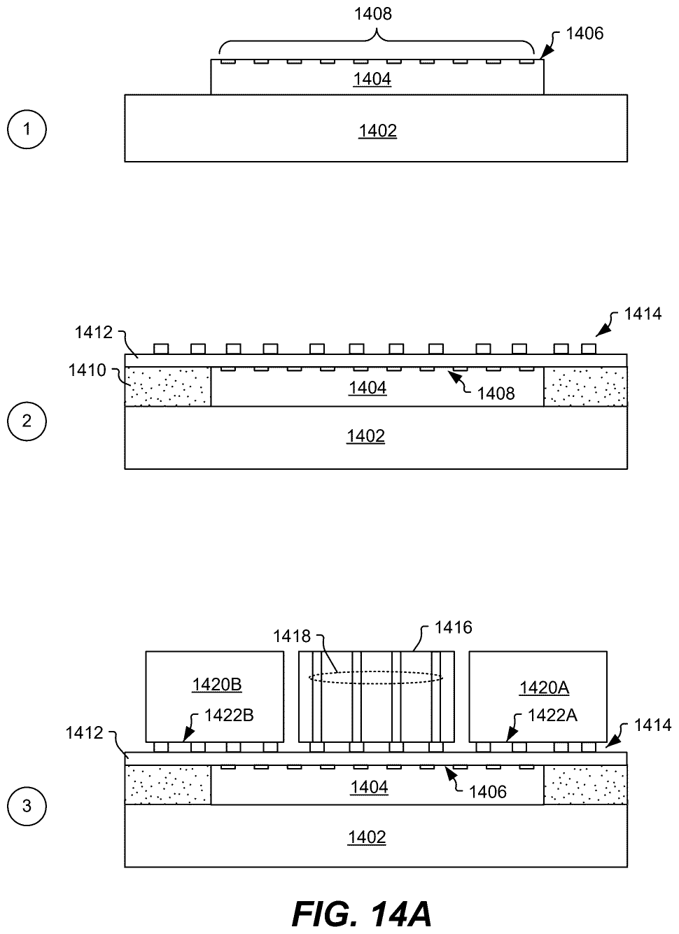

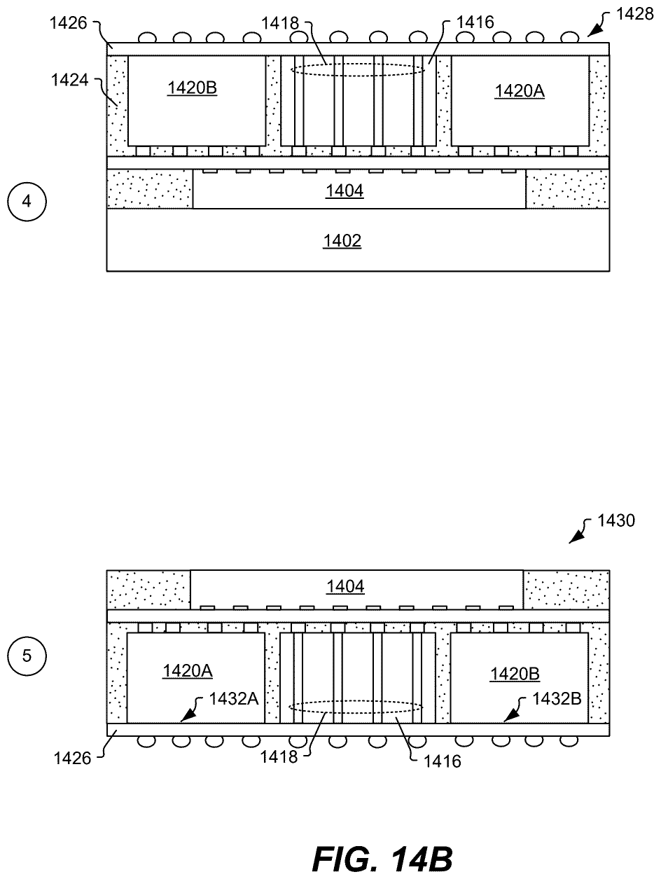

FIGS. 10A-13B depicts schematic cross-sectional representations of Stages during formation of various types of patch components. For example, FIGS. 10A and 10B, together, illustrate an exemplary sequence for fabricating a multi-layer patch component including a semiconductor-based body, FIGS. 11A and 11B, together, illustrate an exemplary sequence for fabricating a multi-layer patch component including a polymer-based body, FIGS. 12A and 12B, together, illustrate an exemplary sequence for fabricating a patch component including a core layer, and FIGS. 13A and 13B, together, illustrate an exemplary sequence for fabricating a patch component without a core layer. The sequence of any of FIGS. 10A-13B may be used to provide (e.g., during fabrication of) the patch component 130 for one or more of the stacked IC devices 100, 200, 300, 400, 500, 600, 700, 800, or 900 of FIGS. 1A-9.

In each of the sequences of FIGS. 10A-13B, two or more stages may be combined in order to simplify and/or clarify the sequence for providing or fabricating the patch component. In some examples, the order of the processes may be changed or modified. In some examples, one or more of the processes may be replaced or substituted without departing from the scope of the disclosure.

In the sequence for fabricating a multi-layer patch component of FIGS. 10A and 10B, Stage 1 of FIG. 10A illustrates a state after formation of openings 1004 in a semiconductor layer 1002. For example, the semiconductor layer 1002 can include a semiconductor wafer, and operations described with reference to FIGS. 10A and 10B can include wafer-level operations. The openings 1004 may be formed using one or more etching operations guided by a patterned resist layer. Alternatively, in some embodiments, the openings 1004 can be formed using one or more drilling operations (e.g., laser drilling or mechanical drilling).

Stage 2 illustrates a state after formation of a layer of a conductive material 1006. The conductive material 1006 (e.g., copper) is formed to fill the openings 1004 or to plate sidewalls of the openings 1004. The layer of the conductive material 1006 may be formed using one or more deposition operations, such as chemical vapor deposition, physical vapor deposition, electroplating, or a combination thereof. At Stage 2, the layer of conductive material 1006 is shown as including a layer on a surface of the semiconductor layer 1002; however, formation of the layer of material on the surface of the semiconductor layer 1002 is optional and may be omitted depending on the specific process operations used to form the layer of conductive material 1006.

Stage 3 illustrates a state after further processing of the layer of conductive material 1006 to electrically isolate vias 1008 from one another and after formation of solder bumps 1010 on the vias 1008. Processing the layer of conductive material 1006 to electrically isolate the vias 1008 is optional. For example, if the processing operations used to form the layer of conductive material 1006 are controlled to avoid formation of the layer of material on the surface of the semiconductor layer 1002 illustrated at Stage 2, then operations to electrically isolate the vias 1008 can be omitted.

In implementations in which portions of the layer of conductive material 1006 are removed to electrically isolate the vias 1008 from one another, the portions of the layer of conductive material 1006 may be removed using one or more material removal processes appropriate to the conductive material, such as one or more etching operations, one or more grinding operations, one or more polishing operations, etc. For example, in some implementations, one or more grinding operations are performed to remove portions of the layer of conductive material 1006 such that ends of the vias 1008 are substantially coplanar with the upper surface of the semiconductor layer 1002.

In the example illustrated at Stage 3, ends of the vias 1008 extend past an upper surface of the semiconductor layer 1002, which is optional. In implementations in which the ends of the vias 1008 are coplanar with the upper surface of the semiconductor layer 1002, the upper surface of the semiconductor layer 1002 may be etched back to provide a desired standoff height of the ends of the vias 1008. Alternatively, one or more additional deposition operations may be performed to form contacts that are electrically connected to the vias 1008 and that extend above the upper surface of the semiconductor layer 1002.

The solder bumps 1010 are optional examples of contacts that can be formed on the vias 1008. In some implementations, the solder bumps 1010 are omitted or replaced with a different type of contact, such as conductive pads. For implementations that include the solder bumps 1010, the solder bumps 1010 may be formed using one or more deposition operations to deposit solder on ends of the vias 1008 (or on contacts electrically connected to the vias 1008). To illustrate, a patterned resist layer can be formed on the surface of the semiconductor layer 1002 and used to guide formation (e.g. deposition) of the solder bumps 1010 on the vias 1008. In some implementations, a barrier layer (e.g., a nickel layer) can be formed on the ends of the vias 1008 before the solder bumps 1010.

Stage 4 illustrates a state after flipping the semiconductor layer 1002 and coupling the semiconductor layer 1002 to a carrier 1014 using a bond layer 1012. For example, for a wafer-level process, the semiconductor layer 1002 may include a semiconductor wafer, and the carrier 1014 may include a carrier wafer. In other examples, the semiconductor layer 1002 includes less than a full wafer, such as a panel or strip, and the carrier 1014 is sized based on a form-factor of the semiconductor layer 1002.

Stage 5 of FIG. 10B illustrates a state after formation of conductive pads 1016. For example, formation of the conductive pads 1016 may include performing one or more grinding operations to remove a portion of the semiconductor layer 1002 to expose ends of the vias 1008. Subsequently, one or more deposition operations guided by a patterned resist layer may be performed to form the conductive pads 1016 on the ends of the vias 1008. The conductive pads 1016 are optional examples of contacts that can be formed on the vias 1008. In some implementations, the conductive pads 1016 are omitted or replaced with a different type of contact, such as solder bumps.

Stage 6 illustrates a state after removal of the bond layer 1012 and the carrier 1014 and after individuation of multiple patch component layers 1020 from the semiconductor layer 1002. In some implementations, one or both sides of the patch component layers 1020 include exposed ends of the vias 1008. In other implementations, one or both sides of the patch component layers 1020 include contacts on ends of the vias 1008, where the contacts include solder bumps (e.g., solder bumps 1010), conductive pads (e.g., conductive pads 1016), or similar structures. One or more delamination processes can be used to remove the bond layer 1012 and the carrier 1014, and one or more cutting operations can be used to separate the patch component layers 1020 from one another.

Stage 7 illustrates a state after two or more of the patch component layers 1020 are stacked to form a patch component 1030. For example, contacts of two or more of the patch component layers 1020 can be joined together, e.g., using reflow operations, to form continuous conductive paths 1024 through the patch component 1030. The continuous conductive paths 1024 correspond to examples of the conductors 106 of FIGS. 1A-9. Optionally, the two or more of the patch component layers 1020 of the patch component 1030 can be at least partially embedded within mold compound 1022.

Formation of the patch components 1030 is complete at Stage 7 of FIG. 10B. In FIG. 10B, the patch component 1030 is illustrated with two patch component layers 1020; however in other embodiments, the patch component 1030 can include more than two patch component layers 1020. The patch component 1030 includes a plurality of vias 1008 (e.g., through silicon vias) extending through semiconductor layers 1002 and interconnected in a stacked arrangement. Exposed ends of each via stack are prepared to form electrical connections with a substrate or a logic die. For example, in FIG. 10B, one end of each via stack includes a solder bump 1010A, and the other end of each via stack includes a conductive pad 1016B.

In some embodiments, one or more of the semiconductor layers 1002 can include circuitry, such as active circuit components (e.g., transistors), passive circuit components (e.g., capacitors, inductors, resistors), conductors (e.g., traces) formed prior to Stage 1 of FIG. 10A or formed between two Stages of FIGS. 10A and 10B (such as between Stages 2 and 3). In such embodiments, the patch component 1030 can include the circuitry 602 of FIG. 6, the conductive path(s) 802 of FIG. 8, or both.

In the sequence for fabricating a multi-layer patch component of FIGS. 11A and 11B, Stage 1 of FIG. 11A illustrates a state after formation of conductive posts 1108 (e.g., copper posts) on a bond layer 1102 formed on a carrier 1104 (e.g., a carrier wafer).

For example, the conductive posts 1108 can be formed using one or more deposition operations, such as electroplating, guided by a patterned resist layer 1106. Openings in the patterned resist layer 1106 define the locations and diameters of the conductive posts 1108.

Stage 2 illustrates a state after removal of the patterned resist layer 1106 and formation of a polymer layer 1110 on the bond layer 1102 (and on or over the conductive posts 1108). The polymer layer 1110 can include a resin, which optionally can include fillers. As an example, the polymer layer 1110 can include mold compound or a resin used for formation of RDLs. One or more deposition operations (e.g., spraying, printing, dispensing) can be used to apply the polymer layer 1110 to the bond layer 1102. The polymer layer 1110 can subsequently be cured or hardened by exposure to light, heat, chemical agents, or combinations thereof.

Stage 3 illustrates a state after processing to expose ends 1112 of the conductive posts 1108. For example, one or more grinding operations, one or more polishing operations, or both, may be performed to remove a portion of the polymer layer 1110 (and optionally a portion of the conductive posts 1108) and expose the ends 1112 of the conductive posts 1108.

Stage 4 of FIG. 11B depicts a state after formation of contacts 1114 on the conductive posts 1108 and removal of the bond layer 1102 and the carrier 1104 to expose second ends 1116 of the conductive posts 1108. For example, the contacts 1114 can be formed using one or more deposition operations (as guided by a patterned resist layer). Formation of the contacts 1114 is optional and is omitted in some implementations. In FIG. 11B, the contacts 1114 are illustrated as conductive pads (e.g., copper pads); however, in other embodiments, the contacts 1114 can include solder bumps in addition to or instead of conductive pads.

In some embodiments, after removal of the bond layer 1102 and the carrier 1104, additional operations can be performed to prepare the second ends 1116 of the conductive posts 1108 for further processing. For example, the additional operations can include one or more planarization operations (e.g., grinding and/or polishing), one or more cleaning operations, etc.

Stage 5 depicts a state after formation of contacts 1118 on the second ends 1116 of the conductive posts 1108 and after individuation of multiple patch components 1120. In the example illustrated in FIG. 11B, each patch component 1120 includes multiple conductive posts 1108 extending through a polymer layer 1110, and each conductive post 1108 includes a contact 1114, 1118 at each end. As described above regarding the contacts 1114, the contacts 1118 can include conductive pads or solder bumps.

Stage 6 illustrates a state after two of the patch components 1120 are stacked to form a patch component 1130. For example, contacts 1114, 1118 of two patch components 1120 can be joined together (e.g., using reflow operations, to form continuous conductive paths 1124 through the patch component 1130). The continuous conductive paths 1124 correspond to examples of the conductors 106 of FIGS. 1A-9. Optionally, the two patch components 1120 of the patch component 1130 can be at least partially embedded within mold compound 1122.

Formation of the patch components 1130 is complete at Stage 6 of FIG. 11B. In FIG. 11B, the patch component 1130 is illustrated with two electrically connected patch components 1120 corresponding to layers of the patch component 1130; however in other embodiments, the patch component 1130 can include more than two electrically connected patch components 1120. The patch component 1130 includes a plurality of conductive posts 1108 extending through polymer layers 1110 and interconnected in a stacked arrangement. Exposed ends of each stack of conductive posts 1108 are prepared to form electrical connections with a substrate or a logic die. For example, in FIG. 11B, one end of each stack of conductive posts 1108 includes a contact 1118A, and the other end of each stack of conductive posts 1108 includes a contact 1114B.

In some embodiments, one or more of the polymer layers 1110 can include circuitry, such as active circuit components (e.g., transistors), passive circuit components (e.g., capacitors, inductors, resistors), conductors (e.g., traces) formed prior to Stage 1 of FIG. 10A (e.g., between the bond layer 1102 and the conductive posts 1108) or formed during formation of one of the contacts 1114 or 1118 (e.g., at Stages 4 or 5). In such embodiments, the patch component 1030 can include the circuitry 602 of FIG. 6, the conductive path(s) 802 of FIG. 8, or both.

In the sequence for fabricating a patch component of FIGS. 12A and 12B, Stage 1 of FIG. 12A illustrates a state after formation or acquisition of a workpiece including a core layer 1202 with a metal layer 1204, 1206 on each side. The core layer 1202 can include a fiber reinforced polymer. The metal layers 1204, 1206 can be coupled to the core layer 1202 using one or more lamination operations. In some embodiments, a thickness of the core layer 1202 is selected based on a target height of a patch component that is being formed. In some embodiments, the core layer 1202 includes circuitry embedded therein, such as one or more embedded dies, one or more embedded capacitors, etc. In such embodiments, the embedded circuitry corresponds to the circuitry 602 of FIG. 6.

Stage 2 illustrates a state after formation of openings 1208 through the metal layers 1204, 1206 and the core layer 1202. In FIG. 12A, two openings 1208, including opening 1208A and opening 1208B, are shown merely for illustration; however, in other embodiments, more than two openings 1208 are formed at Stage 2. For example, the openings 1208 are formed at locations corresponding to desired locations of the conductors (e.g., conductors 106 of any of FIGS. 1A-9) of the patch component being formed. The openings 1208 can be formed using one or more material removal operations, such as mechanical drilling, laser drilling, etching, etc.

Stage 3 illustrates a state after formation of metal layers 1210 within the openings 1208. For example, metal layers 1210A are formed on side walls of the opening 1208A, and metal layers 1210B are formed on side walls of the opening 1208B. The metal layers 1210 can be formed using one or more deposition operations, such as electroplating, physical vapor deposition, chemical vapor deposition, etc.

Stage 4 illustrates a state after formation of patterned resist layers 1212, 1214 on the metal layers 1204, 1206. The patterned resist layers 1212, 1214 define an area for formation of a contact around each of the openings 1208. In some embodiments, the patterned resist layers 1212, 1214 can also define areas for formation of contacts that are not around an opening, such as contacts for conductive paths 802 of FIG. 8, or contacts electrically connected to circuitry 602 of FIG. 6. The patterned resist layers 1212, 1214 can be formed by application of a dry film resist layer to each of the metal layers 1204, 1206 and subsequent exposure and development of the dry film resist layers to form the patterned resist layers 1212, 1214.

Stage 5 of FIG. 12B depicts a state after formation of conductive vias 1216 within the openings 1208 of FIG. 12A. Each conductive via 1216 includes a contact 1218 on one side, and a contact 1220 on the other side. For example, conductive via 1216A includes contact 1218A on a top side (in the orientation illustrated in FIG. 12B) and contact 1220A on a bottom side. Likewise, conductive via 1216B includes contact 1218B on a top side and contact 1220B on a bottom side. In some embodiments, the conductive vias 1216 and contacts 1218, 1220 include two or more electrically connected metal layers. The conductive vias 1216 and contacts 1218, 1220 can be formed using one or more deposition operations, such as electroplating, physical vapor deposition, chemical vapor deposition, etc. as guided by the patterned resist layers 1212, 1214.

Stage 6 illustrates a state after removal of the patterned resist layers 1212, 1214. The patterned resist layers 1212, 1214 can be removed using one or more ashing operations, one or more stripping operations, other cleaning operations, or combinations thereof. Portions 1222 of the metal layer 1204 may remain between the contacts 1218 after removal of the patterned resist layer 1212. Additionally, or alternatively, portions 1224 of the metal layer 1206 may remain between the contacts 1220 after removal of the patterned resist layer 1214.

Stage 7 illustrates a state after removal of at least some of the portions 1222 of the metal layers 1204 and at least some of the portions 1224 of the metal layers 1206. For example, all of the portions 1222 between the contacts 1218 and all of the portions 1224 between the contacts 1220 may be removed to electrically isolate the conductive vias 1216 from one another. The portions 1222, 1224 can be removed by a flash etching process. Alternatively, the portions 1222 between the contacts 1218, the portions 1224 between the contacts 1220, or both, can be selectively removed. For example, portions 1222 of the metal layer 1204 between two contacts 1220 can be retained to define portions of the conductive paths 802 of FIG. 8.

In some embodiments, Stage 7 also follows individuation of a patch component 1230 from one or more other patch components formed concurrently with the patch component 1230. For example, the operations described with reference to Stages 1-6 can be used to form two or more patch components at the same time, in which case Stage 7 follows separation of the patch component 1230 from one or more other patch components using operations such as cutting, sawing, scribing and snapping, etc.

Formation of the patch components 1230 is complete at Stage 7 of FIG. 12B. In FIG. 12B, the patch component 1230 is illustrated as including a core layer 1202; however in other embodiments, two or more of the patch components 1230 can be stacked and interconnected to form a patch component 130 of any of FIGS. 1A-9. The patch component 1230 includes a plurality of conductive vias 1216 extending through the core layers 1202 and contacts 1218, 1220 on ends of the conductive vias 1216.

In the sequence for fabricating a patch component of FIGS. 13A and 13B, Stage 1 of FIG. 13A illustrates a state after formation or acquisition of a workpiece including a core layer 1302 with a release layer 1304, 1306 on each side. The core layer 1302 can include a fiber reinforced polymer. The release layers 1304, 1306 can be coupled to the core layer 1302 using one or more lamination operations.

Stage 2 illustrates a state after formation of a patterned resist layer 1308 on the release layer 1304 and formation of a patterned resist layer 1312 on the release layer 1306. For example, dry film lamination techniques can be used to apply a dry film resist layer to each side of the workpiece of Stage 1, and the dry film resist layers can be exposed and developed to form the patterned resist layers 1308 and 1312.

The patterned resist layer 1308 defines opening 1310 corresponding to locations of contacts of a first patch component that is being formed by the sequence of FIGS. 13A and 13B. In some cases, the patterned resist layer 1308 can also define opening 1310 corresponding to electrical interconnects (e.g. traces) between two or more contacts of the patch component. Similarly, the patterned resist layer 1312 defines openings 1314 corresponding to locations of contacts, and optionally of electrical interconnects, of a second patch component that is being formed by the sequence of FIGS. 13A and 13B. In FIGS. 13A and 13B, the first and second patch components being formed are illustrated as mirror images of one another about a reflection plane along the centerline of the core layer 1302; however, in some embodiments, the first and second patch components are not mirror imaged. For example, the patterned resist layer 1308 can have a number and/or arrangement of the openings 1310 that is different from the number and/or arrangement of the openings 1314 of the patterned resist layer 1312.

Stage 3 illustrates a state after formation of metal layers 1316 and 1318 and removal of the patterned resist layers 1308, 1312. For example, the metal layers 1316, 1318 can be formed using one or more deposition operations, such as electroplating, physical vapor deposition, chemical vapor deposition, etc., as guided by the patterned resist layers 1308, 1312. After deposition of the metal layers 1316, 1318, the patterned resist layers 1308, 1312 can be removed using one or more ashing operations, one or more stripping operations, other cleaning operations, or combinations thereof.

Stage 4 illustrates a state after formation of dielectric layers 1320, 1322 on the metal layers 1316, 1318 and exposed portions of the release layers 1304, 1306. For example, the dielectric layers 1320, 1322 can be applied using one or more dry film lamination operations.

Stage 5 of FIG. 13B depicts a state after formation of openings 1324 in the dielectric layer 1320 and openings 1326 in the dielectric layer 1322. The openings 1324 expose portions of the metal layer 1316, and the openings 1326 expose portions of the metal layer 1318. The openings 1324, 1326 can be formed using one or more selective material removal processes, such as mechanical drilling, laser drilling, or etching.

Stage 6 illustrates a state after formation of metal layers 1328 and 1334. The metal layer 1328 includes conductive vias 1330 within the openings 1324 and contacts 1332 on a surface of the dielectric layer 1320, The conductive vias 1330 are electrically connected to conductive features of the metal layer 1316. Similarly, the metal layer 1334 includes conductive vias 1336 within the openings 1326 and contacts 1338 on a surface of the dielectric layer 1322. The conductive vias 1330 are electrically connected to conductive features of the metal layer 1318. In some embodiments, the metal layer 1328, the metal layer 1334, or both, include other features, such as traces, defining portions of the conductive paths 802 of FIG. 8.

The metal layers 1328, 1334 can be formed using one or more deposition operations, such as electroplating, physical vapor deposition, chemical vapor deposition, etc., as guided by patterned resist layers. For example, formation of the metal layers 1328, 1334 can be performed in the same manner as formation of the metal layers 1316, 1318, as described with reference to Stages 2 and 3 of FIG. 13A.

Stage 7 illustrates a state after formation of dielectric layers 1340, 1348 and metal layers 1342, 1350. The dielectric layers 1340, 1348 and the metal layers 1342, 1350 can be formed by repeating operations described with reference to Stages 4-6. The metal layer 1342 includes conductive vias 1344 that extend through the dielectric layer 1340 and contacts 1346 on a surface of the dielectric layer 1340, The conductive vias 1344 are electrically connected to conductive features of the metal layer 1328. Similarly, the metal layer 1350 includes conductive vias 1352 that extend through the dielectric layer 1348 and contacts 1354 on a surface of the dielectric layer 1348, The conductive vias 1352 are electrically connected to conductive features of the metal layer 1334.

Stage 8 illustrates a state after formation of additional dielectric layers 1356, 1360 and additional metal layers 1358, 1362 by repeating the operations described with reference to Stages 4-6. Although Stage 8 illustrates one additional dielectric layer and one additional metal layer on each side of the workpiece (e.g., the dielectric layer 1356 and the metal layer 1358 on a top side (in the orientation illustrated in FIG. 13B), and the dielectric layer 1360 and the metal layer 1362 on a bottom side), more than one additional dielectric layer and more than one additional metal layer can be formed on one side or on both sides of the workpiece at Stage 8. The number of additional dielectric layers and metal layers depends on a target thickness of a patch component 1370 and heights of the respective layers.

Stage 8 also follows separation of the patch components 1370 from the release layers 1304, 1306, and in some embodiments, individuation of a patch component 1370 from other patch components formed concurrently with the patch components 1370. For example, the operations described with reference to Stages 1-8 can be used to form two or more patch components at the same time on each side of the core layer 1302, in which case, Stage 8 follows separation of the patch components 1370A from one or more other patch components formed on the top of the core layer 1302 (e.g., using operations such as cutting, sawing, scribing and snapping, etc.) and separation of the patch components 1370B from one or more other patch components formed on the bottom of the core layer 1302 (e.g., using operations such as cutting, sawing, scribing and snapping, etc.).

Formation of a patch components 1370 is complete at Stage 8 of FIG. 13B. In FIG. 13B, the patch components 1370 are illustrated as including via stacks 1364 that extend through multiple layers of dialectic material. The via stacks 1364 can correspond to the conductors 106 of the patch component 130 of any of FIGS. 1A-9.

### Exemplary Sequences for Fabricating Stacked IC Devices

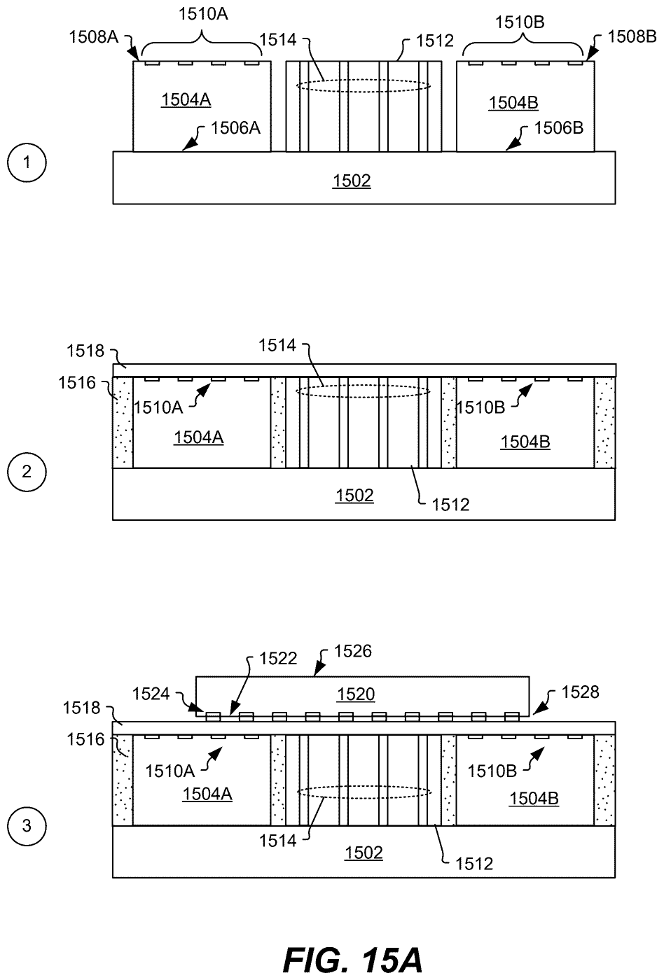

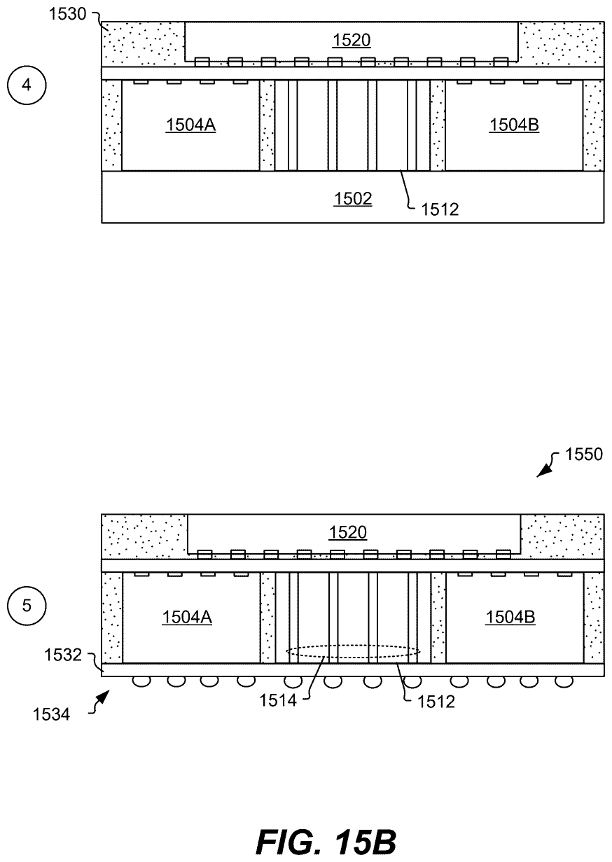

FIGS. 14A-15B depicts schematic cross-sectional representations of Stages during formation of stacked IC devices. For example, FIGS. 14A and 14B, together, illustrate an exemplary first sequence for fabricating a stacked IC device, and FIGS. 15A and 15B, together, illustrate an exemplary second sequence for fabricating a stacked IC device. Eather of the sequences of FIGS. 14A-15B may be used to provide (e.g., during fabrication of) one or more of the stacked IC devices 100, 200, 300, 400, 500, 600, 700, 800 or 900 of FIGS. 1A-9.

In each of the sequences of FIGS. 14A-15B, two or more stages may be combined in order to simplify and/or clarify the sequence for providing or fabricating the stacked IC device. In some examples, the order of the processes may be changed or modified. In some examples, one or more of the processes may be replaced or substituted without departing from the scope of the disclosure.

In the first sequence for fabricating a stacked IC device of FIGS. 14A and 14B, Stage 1 of FIG. 14A illustrates a state after a logic die 1404 is coupled to a carrier 1402. The logic die 1404 is positioned in a face-up orientation, such that a back of the logic die 1404 is coupled to the carrier 1402, and contacts 1408 on a face 1406 of the logic die 1404 are away from the carrier 1402. The logic die 1404 can be adhered to the carrier 1402 using an adhesive layer.

Although FIGS. 14A and 14B illustrate a single logic die 1404, the operations described herein can be performed for more than one logic die 1404 at a time. For example, the carrier 1402 can be a carrier wafer such as used for reconstructed wafer level operations. In this example, a plurality (e.g., tens or hundreds) of logic dies 1404 can be coupled to the carrier 1402 at Stage 1, where each logic die is for a respective stacked IC device being formed by the sequence of FIGS. 14A and 14B. In some embodiments, the sequence of FIGS. 14A and 14B can be used to form one or more stacked IC devices that each include two or more logic dies, respectively (e.g., one of the stacked IC devices 800 or 900 of FIGS. 8 and 9). In such embodiments, the two or more logic dies 1404 of each stacked IC device being formed by the sequence of FIGS. 14A and 14B are coupled to the carrier 1402 at Stage 1.

Stage 2 illustrates a state after application of mold compound 1410 to at least partially encapsulate the logic die 1404, and after formation of RDLs 1412. The RDLs 1412 are optional and are omitted in some embodiments. When present, the RDLs 1412 remap the contacts 1408 of the logic die 1404 to contacts 1414 at positions more convenient for interconnect with contacts of memory stacks, a patch component, etc. The mold compound 1410 can be formed by application of a resin (e.g., epoxy) to the carrier 1402 and subsequent curing by exposure to light, heat, and/or chemical hardening agents. The RDLs 1412 can be built up using patterned metal layers that are separated by dielectric layers and selectively interconnected by conductive vias.

Stage 3 illustrates a state after two or more memory stacks 1420 and one or more patch components 1416 are electrically connected to the logic die 1404. In the example, illustrated in FIG. 14A, the memory stacks 1420 include a memory stack 1420A and a memory stack 1420B, and the patch component 1416 is disposed between the memory stack 1420A and the memory stack 1420B. A face 1422 of a die of each of the memory stacks 1420 is oriented toward the face 1406 of the logic die 1404. For example, a face 1422A of a die of the memory stack 1420A is toward the face 1406 of the logic die, and a face 1422B of a die of the memory stack 1420B is toward the face 1406 of the logic die.

Each of the memory stacks 1420 corresponds to one of the memory stacks 104 of any of FIGS. 1A-9. The patch component 1416 includes or corresponds to any of the patch components 130 of FIGS. 1A-9, the patch component 1030 of FIG. 10B, the patch component 1130 of FIG. 11B, the patch component 1230 of FIG. 12B, or the patch component 1370 of FIG. 13B. The patch component 1416 includes conductors 1418 corresponding to the conductors 106 of FIGS. 1A-9.

Stage 4 of FIG. 14B illustrates a state after application of mold compound 1424 to at least partially encapsulate the patch component 1416 and the memory stacks 1420, and after formation of RDLs 1426. Formation of the mold compound 1424 and the RDLs 1426 is optional and is omitted in some embodiments. When present, the RDLs 1426 remap the contacts of the conductors 1418 of the patch component 1416 to contacts 1428 (e.g., solder bumps) at positions more convenient for interconnect with contacts of a substrate. The mold compound 1424 and the RDLs 1426 can be formed using similar operations to those described with reference to Stage 2 of FIG. 14A.

Stage 5 of FIG. 14B illustrates a state after separation of a stacked IC device 1430 from the carrier 1402 and separation of the stacked IC device 1430 from other stacked IC devices formed at the same time. For example, when reconstructed wafer-level operations are used to form the stacked IC device 1430, a plurality of additional stacked IC devices can be formed at the same time as the stacked IC device 1430 and on the same carrier 1402. In this example, individuation operations, such as cutting, sawing, and/or scribing and snapping, can be used to separate the stacked IC devices from one another.

In some embodiments, formation of the stacked IC device 1430 is complete at Stage 5. For example, in some such embodiments, the RDLs 1426 function as a substrate of the stacked IC device 1430. Alternatively, the RDLs 1426 can be coupled, via the contacts 1428 to another substrate, such as the substrate 102 of any of FIGS. 4-9. In other embodiments, the RDLs 1426 are omitted, in which case, the stacked IC device 1430 of Stage 5 is coupled to a substrate. For example, a back of a bottom die of each memory stack 1420 (e.g., a back 1432A of the memory stacks 1420A and a back 1432B of the memory stack 1420B) can be adhered to the substrate (e.g., using one of the adhesive layers 222 described with reference to FIG. 2) and contacts of the conductors 1418 of the patch component 1416 can be electrically connected to contacts of the substrate.

In the second sequence for fabricating a stacked IC device of FIGS. 15A and 15B, Stage 1 of FIG. 15A illustrates a state after two or more memory stacks 1504 and one or more patch components 1512 are coupled to a carrier 1502. For example, the memory stacks 1504 and the patch component(s) 1512 can be adhered to the carrier 1502 using an adhesive layer.

The memory stacks 1504 are positioned in a face-up orientation relative to the carrier 1502, such that a back 1506 of a bottom die of each memory stack 1504 is coupled to the carrier 1502, and contacts 1510 on a face 1508 of a top die of each memory stack 1504 are away from the carrier 1502. For example, a back 1506A of a bottom die of the memory stack 1504A is coupled to the carrier 1502, and contacts 1510A on a face 1508A of a top die of the memory stack 1504A are away from the carrier 1502. Further, a back 1506B of a bottom die of the memory stack 1504B is coupled to the carrier 1502, and contacts 1510B on a face 1508B of a top die of the memory stack 1504B are away from the carrier 1502.

Although FIGS. 15A and 15B illustrate two memory stacks 1504 and one patch component 1512, the operations described herein can be performed for more than two memory stacks 1504 and/or more than one patch component 1512 at a time. For example, the carrier 1502 can be a carrier wafer such as used for reconstructed wafer level operations. In this example, a plurality (e.g., tens or hundreds) of stacked IC devices can be formed concurrently, and each such stacked IC device can include at least two memory stacks 1504 and at least one patch component 1512.

Each of the memory stacks 1504 corresponds to one of the memory stacks 104 of any of FIGS. 1A-9. The patch component 1512 includes or corresponds to any of the patch components 130 of FIGS. 1A-9, the patch component 1030 of FIG. 10B, the patch component 1130 of FIG. 11B, the patch component 1230 of FIG. 12B, or the patch component 1370 of FIG. 13B. The patch component 1512 includes conductors 1514 corresponding to the conductors 106 of FIGS. 1A-9.

Stage 2 illustrates a state after application of mold compound 1516 to at least partially encapsulate the memory stacks 1504 and the patch component 1512 and after formation of RDLs 1518. Formation of the mold compound 1516 and the RDLs 1518 is optional and is omitted in some embodiments. When present, the RDLs 1518 remap the contacts of the conductors 1514 of the patch component 1512, the contacts 1510 of the memory stacks 1504, or both, to positions more convenient for interconnection with contacts of one or more logic dies. The mold compound 1516 can be formed by application of a resin (e.g., epoxy) to the carrier 1502 and subsequent curing by exposure to light, heat, and/or chemical hardening agents. The RDLs 1518 can be built up using patterned metal layers that are separated by dielectric layers and selectively interconnected by conductive vias.

Stage 3 illustrates a state after one or more logic dies (e.g., illustrative logic die 1520) are electrically connected, in a face-to-face arrangement, to the memory stacks 1504 and the patch component 1512. For example, a face 1522 of the logic die 1520 is oriented toward the memory stacks 1504 and the patch component 1512, and a back 1526 of the logic die 1520 is oriented away from the memory stacks 1504 and the patch component 1512. Contacts 1524 on the face 1522 of the logic die 1520 are electrically connected, through interconnects 1528, to contacts of the RDLs 1518, if the RDLs 1518 are present. Alternatively, if the RDLs 1518 are omitted, the contacts 1524 on the face 1522 of the logic die 1520 are electrically connected directly, via the interconnects 1528, to the contacts 1510 of the memory stacks 1504 and contacts of the conductors 1514.

Stage 4 of FIG. 15B illustrates a state after application of mold compound 1530 to at least partially encapsulate the logic die 1520. Formation of the mold compound 1530 is optional and is omitted in some embodiments.

Stage 5 illustrates a state after separation of a stacked IC device 1550 from the carrier 1502 and separation of the stacked IC device 1550 from other stacked IC devices formed at the same time. For example, when reconstructed wafer-level operations are used to form the stacked IC device 1550, a plurality of additional stacked IC devices can be formed at the same time as the stacked IC device 1550 and on the same carrier 1502. In this example, individuation operations, such as cutting, sawing, and/or scribing and snapping, can be used to separate the stacked IC devices from one another.

The state illustrated at Stage 5 also follows attachment of the memory stacks 1504 and the patch component 1512 to layers 1532. The layers 1532 can include layers built up directly on a surface exposed by removal of the carrier 1502 (e.g., the layers 1532 can include RDLs), or the layers 1532 can be pre-formed and attached to the surface exposed by removal of the carrier 1502 (e.g., the layers 1532 can include a pre-formed substrate). In either case, the layers 1532 include two or more metal layers patterned to form conductive features (e.g., traces), separated from one another by dielectric layers, and interconnected by vias to form conductive paths between metal layers. The layers 1532 remap contacts of the conductors 1514 to contacts 1534.

### Exemplary Flow Diagram of Method for Fabricating Stacked IC Devices

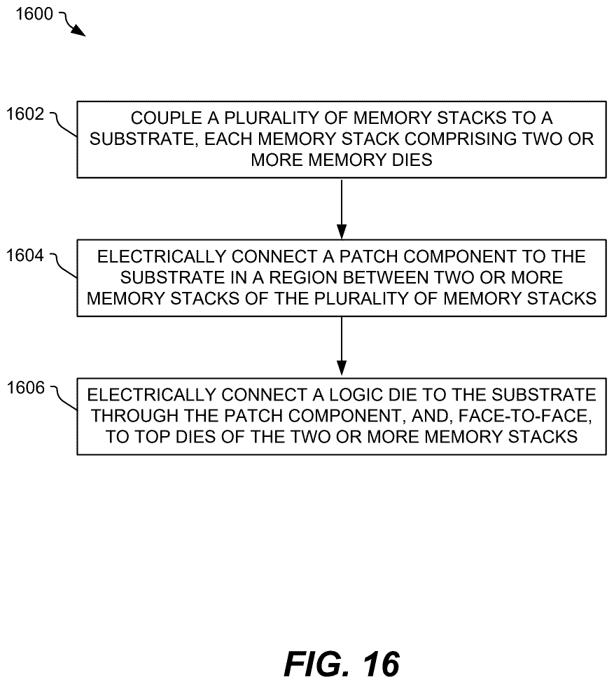

In some implementations, fabricating a stacked IC device includes several processes. FIG. 16 illustrates an exemplary flow diagram of a method 1600 for providing or fabricating a stacked IC device. In some implementations, the method 1600 of FIG. 16 can be used to provide or fabricate any of the stacked IC devices of FIGS. 1A-9, 14B, and 15B. It should be noted that the method 1600 may combine one or more processes in order to simplify and/or clarify the method 1600 for providing or fabricating a stacked IC device. In some implementations, the order of the processes may be changed or modified.

The method 1600 includes, at block 1602, coupling a plurality of memory stacks to a substrate, each memory stack comprising two or more memory dies. For example, the memory stacks can include or correspond to the memory stacks 104 of any of FIGS. 1A-9, which are attached to the substrate 102, either directly or through RDLs 420. As another example, the memory stacks can include or correspond to the memory stacks 1420 of FIGS. 14A and 14B, which can optionally be connected to the RDLs 1426, in which case the RDLs 1426 can correspond to the substrate. Alternatively, the RDLs 1426 can be omitted, and the memory stacks 1420 can be coupled to a pre-formed substrate. As another example, the memory stacks can include or correspond to the memory stacks 1504 of FIGS. 15A and 15B, which are connected to the layers 1532, where the layers 1532 correspond to the substrate.

The method 1600 includes, at block 1604, electrically connecting a patch component to the substrate in a region between two or more memory stacks of the plurality of memory stacks. For example, the patch component can include or correspond to the patch component 130 of any of FIGS. 1A-9, which is electrically connected to the substrate 102, either directly or through RDLs 420. As another example, the patch component can include or correspond to the patch component 1416 of FIGS. 14A and 14B, which can optionally be connected to the RDLs 1426, in which case the RDLs 1426 can correspond to the substrate. Alternatively, the RDLs 1426 can be omitted, and the patch component 1416 can be electrically connected to a pre-formed substrate. As another example, the patch component can include or correspond to the patch component 1512 of FIGS. 15A and 15B, which is electrically connected to the layers 1532, where the layers 1532 correspond to the substrate.

The method 1600 includes, at block 1606, electrically connecting a logic die to the substrate through the patch component, and, face-to-face, to top dies of the two or more memory stacks. For example, the logic die can correspond to the logic die(s) 110 of any of FIGS. 1A-9, which are electrically connected face-to-face with a top die of each memory stack 104 and electrically connected, through the patch component 130, to the substrate 102. As another example, the logic die can correspond to the logic die 1404 of FIGS. 14A and 14B, which are electrically connected face-to-face with a top die of each memory stack 1420 and electrically connected, through the patch component 1416, to the RDLs 1426, to a pre-formed substrate, or to both. As another example, the logic die can correspond to the logic die 1520 of FIGS. 15A and 15B, which are electrically connected face-to-face with a top die of each memory stack 1504 and electrically connected, through the patch component 1512, to the layers 1532, which correspond to the substrate.

In some embodiments, the method 1600 also includes electrically connecting a second logic die to the substrate through the patch component, and, face-to-face, to top dies of the two or more additional memory stacks of the plurality of memory stacks. In such embodiments, the second logic die can be electrically connected to the logic die through redistribution layers, through the patch component (e.g., as described with reference to FIG. 8), or both.

### Exemplary Electronic Devices

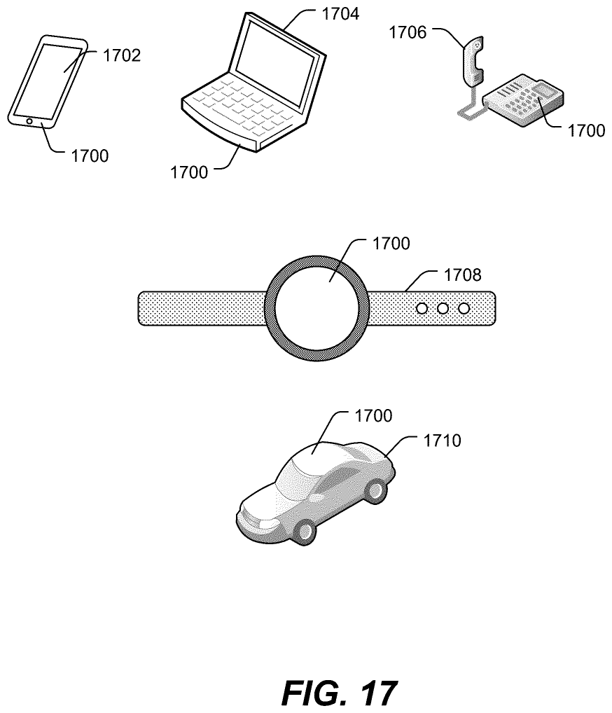

FIG. 17 illustrates various electronic devices that may include or be integrated with any of the stacked IC devices 100, 200, 300, 400, 500, 600, 700, 800, 900, 1430, or 1550 of any of FIG. 1A-9, 14B, or 15B. For example, a mobile phone device 1702, a laptop computer device 1704, a fixed location terminal device 1706, a wearable device 1708, or a vehicle 1710 (e.g., an automobile or an aerial device) may include a device 1700. The device 1700 can include, for example, any of the stacked IC devices 100, 200, 300, 400, 500, 600, 700, 800, 900, 1430, or 1550 of any of FIG. 1A-9, 14B, or 15B. The devices 1702, 1704, 1706, 1708 and the vehicle 1710 illustrated in FIG. 17 are merely exemplary. Other electronic devices may also feature the device 1700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1A-17 may be rearranged and/or combined into a single component, process, feature, or function or embodied in several components, processes, or functions. Additional elements, components, processes, and/or functions may also be added without departing from the disclosure. It should also be noted FIGS. 1A-17 and their corresponding description in the present disclosure is not limited to dies and/or ICs. In some implementations, FIGS. 1A-17 and their corresponding description may be used to manufacture, create, provide, and/or produce devices and/or integrated devices. In some implementations, a device may include a die, an integrated device, an integrated passive device (IPD), a die package, an IC device, a device package, an IC package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, and/or integrated circuits. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” and “electrically connected” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, a reflow process, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a first memory stack including two or more memory dies coupled to a substrate; a second memory stack including two or more memory dies coupled to the substrate; a logic die electrically connected to memory dies of the first memory stack through face-to-face connections to a top die of the first memory stack and electrically connected to memory dies of the second memory stack through face-to-face connections to a top die of the second memory stack; and a patch component disposed in a region between the first memory stack and the second memory stack, the patch component including conductors that electrically connect the logic die to the substrate.

Example 2 includes the device of Example 1, wherein the first memory stack comprises a high bandwidth memory (HBM) stack.

Example 3 includes the device of Example 1 or Example 2, wherein the top die of the first memory stack comprises a memory controller for the two or more memory dies of the first memory stack.

Example 4 includes the device of any of Examples 1 to 3, wherein a body of the patch component comprises mold compound, and wherein the conductors comprise through mold vias extending through the mold compound.

Example 5 includes the device of any of Examples 1 to 3, wherein a body of the patch component comprises a multilayer structure, and wherein the conductors comprise stacked and electrically connected conductors extending through layers of the multilayer structure.

Example 6 includes the device of any of Examples 1 to 3, wherein a body of the patch component comprises a core layer, and wherein the conductors comprise vias extending through the core layer.

Example 7 includes the device of any of Examples 1 to 3, wherein a body of the patch component comprises a semiconductor layer, and wherein one or more of the conductors comprises a through silicon via extending through the semiconductor layer.

Example 8 includes the device of any of Examples 1 to 7, wherein the patch component includes active circuit components, passive circuit components, or both.

Example 9 includes the device of any of Examples 1 to 8 and further includes one or more additional memory stacks comprising two or more memory dies coupled to the substrate; and a second logic die electrically connected to memory dies of the one or more additional memory stacks through face-to-face connections to a top die of each of the one or more additional memory stacks, wherein the conductors of the patch component electrically connect the second logic die to the substrate.

Example 10 includes the device of Example 9 and further includes redistribution layers between the logic die and the first memory stack, between the logic die and the second memory stack, between the second logic die and the one or more additional memory stacks, and electrically connecting the logic die to the second logic die.

Example 11 includes the device of Example 9 or Example 10, wherein the logic die is electrically connected to the second logic die through the patch component.

According to Example 12, a device includes a first memory stack including two or more memory dies coupled to a substrate; a second memory stack including two or more memory dies coupled to the substrate; a first logic die electrically connected to memory dies of the first memory stack through face-to-face connections to a top die of the first memory stack; a second logic die electrically connected to memory dies of the second memory stack through face-to-face connections to a top die of the second memory stack; and a patch component disposed in a region between the first memory stack and the second memory stack, the patch component including first conductors that electrically connect the first logic die to the substrate and second conductors that electrically connect the second logic die to the substrate.

Example 13 includes the device of Example 12, wherein the first memory stack comprises a first high bandwidth memory stack and the second memory stack comprises a second high bandwidth memory stack.

Example 14 includes the device of Example 12 or Example 13, wherein the top die of the first memory stack comprises a first memory controller for the two or more memory dies of the first memory stack, and the top die of the second memory stack comprises a second memory controller for the two or more memory dies of the second memory stack.

Example 15 includes the device of any of Examples 12 to 14, wherein the first logic die and the second logic die are electrically connected to one another through the patch component.

Example 16 includes the device of any of Examples 12 to 15 and further includes redistribution layers disposed between the first logic die and the first memory stack, between the second logic die and the second memory stack, and electrically connecting the first logic die to the second logic die.

According to Example 17, a method includes coupling a plurality of memory stacks to a substrate, each memory stack comprising two or more memory dies; electrically connecting a patch component to the substrate in a region between two or more memory stacks of the plurality of memory stacks; and electrically connecting a logic die to the substrate through the patch component, and, face-to-face, to top dies of the two or more memory stacks.

Example 18 includes the method of Example 17 and further includes electrically connecting a second logic die to the substrate through the patch component, and, face-to-face, to top dies of two or more additional memory stacks of the plurality of memory stacks.

Example 19 includes the method of Example 17 or Example 18 and further includes electrically connecting the logic die to the second logic die through the patch component.

Example 20 includes the method of any of Examples 18 to 19 and further includes electrically connecting the logic die to the second logic die through redistribution layers.

1. A device comprising:
a first memory stack comprising two or more memory dies coupled to a substrate;
a second memory stack comprising two or more memory dies coupled to the substrate;
a logic die electrically connected to memory dies of the first memory stack through face-to-face connections to a top die of the first memory stack and electrically connected to memory dies of the second memory stack through face-to-face connections to a top die of the second memory stack; and
a patch component disposed in a region between the first memory stack and the second memory stack, the patch component including conductors that electrically connect the logic die to the substrate.

2. The device of claim 1, wherein the first memory stack comprises a high bandwidth memory (HBM) stack.

3. The device of claim 1, wherein the top die of the first memory stack comprises a memory controller for the two or more memory dies of the first memory stack.

4. The device of claim 1, wherein a body of the patch component comprises mold compound, and wherein the conductors comprise through mold vias extending through the mold compound.

5. The device of claim 1, wherein a body of the patch component comprises a multilayer structure, and wherein the conductors comprise stacked and electrically connected conductors extending through layers of the multilayer structure.

6. The device of claim 1, wherein a body of the patch component comprises a core layer, and wherein the conductors comprise vias extending through the core layer.

7. The device of claim 1, wherein a body of the patch component comprises a semiconductor layer, and wherein one or more of the conductors comprises a through silicon via extending through the semiconductor layer.

8. The device of claim 1, wherein the patch component includes active circuit components, passive circuit components, or both.

9. The device of claim 1, further comprising:
one or more additional memory stacks comprising two or more memory dies coupled to the substrate; and
a second logic die electrically connected to memory dies of the one or more additional memory stacks through face-to-face connections to a top die of each of the one or more additional memory stacks,
wherein the conductors of the patch component electrically connect the second logic die to the substrate.

10. The device of claim 9, further comprising redistribution layers between the logic die and the first memory stack, between the logic die and the second memory stack, between the second logic die and the one or more additional memory stacks, and electrically connecting the logic die to the second logic die.

11. The device of claim 9, wherein the logic die is electrically connected to the second logic die through the patch component.

12. A device comprising:
a first memory stack comprising two or more memory dies coupled to a substrate;
a second memory stack comprising two or more memory dies coupled to the substrate;
a first logic die electrically connected to memory dies of the first memory stack through face-to-face connections to a top die of the first memory stack;
a second logic die electrically connected to memory dies of the second memory stack through face-to-face connections to a top die of the second memory stack; and
a patch component disposed in a region between the first memory stack and the second memory stack, the patch component including first conductors that electrically connect the first logic die to the substrate and second conductors that electrically connect the second logic die to the substrate.

13. The device of claim 12, wherein the first memory stack comprises a first high bandwidth memory stack and the second memory stack comprises a second high bandwidth memory stack.

14. The device of claim 12, wherein the top die of the first memory stack comprises a first memory controller for the two or more memory dies of the first memory stack, and the top die of the second memory stack comprises a second memory controller for the two or more memory dies of the second memory stack.

15. The device of claim 12, wherein the first logic die and the second logic die are electrically connected to one another through the patch component.

16. The device of claim 12, further comprising redistribution layers disposed between the first logic die and the first memory stack, between the second logic die and the second memory stack, and electrically connecting the first logic die to the second logic die.

17. A method comprising:
coupling a plurality of memory stacks to a substrate, each memory stack comprising two or more memory dies;
electrically connecting a patch component to the substrate in a region between two or more memory stacks of the plurality of memory stacks; and
electrically connecting a logic die to the substrate through the patch component, and, face-to-face, to top dies of the two or more memory stacks.

18. The method of claim 17, further comprising electrically connecting a second logic die to the substrate through the patch component, and, face-to-face, to top dies of two or more additional memory stacks of the plurality of memory stacks.

19. The method of claim 18, further comprising electrically connecting the logic die to the second logic die through the patch component.

20. The method of claim 18, further comprising electrically connecting the logic die to the second logic die through redistribution layers.
